(19) United States
(12) Patent Application Publication
(10) Pub. No.: US 2007/0252515 A1
(43) Pub. Date: Nov. 1, 2007

(54) Electroluminescent device including an anthracene derivative

(75) Inventors: Lelia Cosimbescu, Rochester, NY (US); Scott R. Conley, Rochester, NY (US); Zbyslaw R. Owczarczyk, Webster, NY (US)

Correspondence Address: Paul A. Leipold;Patent Legal Staff, Eastman Kodak Company, 343 State Street, Rochester, NY, 14650-2201, US

(73) Assignee: Eastman Kodak Company

(21) Appl. No.: 11/412,285

(22) Filed: Apr. 27, 2006

(51) Int. Cl. H01L 51/54

(52) U.S. Cl. 313/504; 313/506; 257/E51.049; 428/690; 428/917

(57) ABSTRACT

An OLED device comprises a cathode, an anode, and has therebetween a light emitting layer (LEL), at least one layer between the cathode and anode comprising a carbocyclic 2-aryl-9,10-biphenylanthracene compound containing a total of 8-12 aromatic rings, wherein the 6-substituent is hydrogen or an alkyl group and the 2-substituent is: (A) an unsubstituted phenyl group; (B) a phenyl group substituted with (a) a fluoro, a cyano, or an alkyl group or (b) a m- or p-phenyl group; or (C) a substituted or unsubstituted fused ring aromatic group.

### CROSS-REFERENCE TO RELATED APPLICATIONS

This application is cofiled as part of a group of five applications under attorney Docket Nos. 91082, 91926, 92030, 92055, and 92056.

### FIELD OF THE INVENTION

This invention relates to an electroluminescent (EL) device comprising a light-emitting layer and including at least one layer containing an anthracene derivative that can provide desirable electroluminescent properties.

### BACKGROUND OF THE INVENTION

While organic electroluminescent (EL) devices have been known for over two decades, their performance limitations have represented a barrier to many desirable applications. In simplest form, an organic EL device is comprised of an anode for hole injection, a cathode for electron injection, and an organic medium sandwiched between these electrodes to support charge recombination that yields emission of light. These devices are also commonly referred to as organic light-emitting diodes, or OLEDs. Representative of earlier organic EL devices are Gurnee et al. U.S. Pat. No. 3,172,862, issued Mar. 9, 1965; Gurnee U.S. Pat. No. 3,173,050, issued Mar. 9, 1965; Dresner, “Double Injection Electroluminescence in Anthracene”, RCA Review, 30, 322, (1969); and Dresner U.S. Pat. No. 3,710,167, issued Jan. 9, 1973. The organic layers in these devices, usually composed of a polycyclic aromatic hydrocarbon, were very thick (much greater than 1 μm). Consequently, operating voltages were very high, often greater than 100V.

More recent organic EL devices include an organic EL element consisting of extremely thin layers (e.g. <1.0 μm) between the anode and the cathode. Herein, the term “organic EL element” encompasses the layers between the anode and cathode. Reducing the thickness lowered the resistance of the organic layers and enabled devices to operate at much lower voltage. In a basic two-layer EL device structure, described first in U.S. Pat. No. 4,356,429, one organic layer of the EL element adjacent to the anode is specifically chosen to transport holes, and therefore is referred to as the hole-transporting layer, and the other organic layer is specifically chosen to transport electrons and is referred to as the electron-transporting layer. Recombination of the injected holes and electrons within the organic EL element results in efficient electroluminescence.

There have also been proposed three-layer organic EL devices that contain an organic light-emitting layer (LEL) between the hole-transporting layer and electron-transporting layer, such as that disclosed by C. Tang et al. (J. Applied Physics, Vol. 65, 3610 (1989)). The light-emitting layer commonly consists of a host material doped with a guest material, otherwise known as a dopant. Still further, there has been proposed in U.S. Pat. No. 4,769,292 a four-layer EL element comprising a hole injecting layer (HIL), a hole-transporting layer (HTL), a light-emitting layer (LEL) and an electron-transporting/injecting layer (ETL). These structures have resulted in improved device efficiency.

Since these early inventions, further improvements in device materials have resulted in improved performance in attributes such as color, stability, luminance efficiency and manufacturability, e.g., as disclosed in U.S. Pat. No. 5,061,569, U.S. Pat. No. 5,409,783, U.S. Pat. No. 5,554,450, U.S. Pat. No. 5,593,788, U.S. Pat. No. 5,683,823, U.S. Pat. No. 5,908,581, U.S. Pat. No. 5,928,802, U.S. Pat. No. 6,020,078, and U.S. Pat. No. 6,208,077, amongst others.

EL devices that emit white light have proven to be very useful. They can be used with color filters to produce full-color display devices. They can also be used with color filters in other multicolor or functional-color display devices. White EL devices for use in such display devices are easy to manufacture, and they produce reliable white light in each pixel of the displays. Although the OLEDs are referred to as white, they can appear white or off-white, for this application, the CIE coordinates of the light emitted by the OLED are less important than the requirement that the spectral components passed by each of the color filters be present with sufficient intensity in that light. Thus there is a need for new materials that provide high luminance intensity for use in white OLED devices.

Anthracene based hosts are often used in EL devices. A useful class of 9,10-di-(2-naphthyl)anthracene hosts has been disclosed in U.S. Pat. No. 5,935,721. Bis-anthracene compounds used in the luminescent layer with an improved device half-life have been disclosed in U.S. Pat. No. 6,534,199 and U.S. Pat. No. 2002/0136922. Electroluminescent devices with improved luminance using an anthracene compound have been disclosed in U.S. Pat. No. 6,582,837. Anthracenes have also been used in the hole-transporting layer (HTL) as disclosed in U.S. Pat. No. 6,465,115. In addition there are other disclosures of using anthracene materials in EL devices, for example, U.S. Pat. No. 5,972,247, JP 2001/097897, JP 2000/273056, US 2002/0048687, WO 2003/060956, WO 2002/088274, WO 2003/087023, EP 0429821, WO 2003/007658, JP 2000/053677, and JP 2001/335516.

K. Kim and coworkers (US 2004/0023060) describe double spiro anthracene derivatives. Among the materials reported are those which have a double spiro group located in the 2-positions of a 9,10 substituted anthracene, although materials of this nature may have a large number of carbocyclic rings and may have a high sublimation temperature.

S. Yoon and coworkers, WO 2003/060956, describe anthracene materials in which one to two imidazole groups are located in the 2 or 2,6-positions of 9,10 substituted anthracenes. I. Hidetsugu et al., JP 2004/059535, describe similar 9,10 substituted anthracene in which aryl and heteroaryl groups are located in the 2- or 2,6-positions.

I. Hidetsugu and coworkers, JP 2005/170911, further report anthracene materials substituted in the 2-position with a phenyl group. The phenyl group is substituted in the ortho-position with an aryl group, however materials of this type, when used in EL devices, may result in poor stability. Illustrative compounds are substituted with the same substituent in the 9- and 10-positions.

I. Hidetsugu et al., JP 2001/335516 also report the use of substituted anthracenes as hosts for light-emitting materials. Examples are described in which the use of anthracenes substituted with simple biphenyl groups in the 9,10-positions (C-1 and C-2 of comparative examples 1 and 2) afford inferior light-emission relative to more complex anthracenes having biphenyl groups that are further substituted.

S. Conley, W. Vreeland, and L. Cosimbescu, US 2005/211958, describe anthracene compounds bearing at least one aryl ring in the 2-position and having a hydrogen or an alkyl group in the 6-position and having up to 12 aromatic carbocyclic rings including at least one naphthalene group in the 9-position of the anthracene group and an aryl group in the 10-position. However, anthracenes that have been described previously may not provide all the desirable embodiments of a host material.

Despite these advances, there is a continuing need for hosts that, provide desirable hues and offer reduced drive voltage, improved luminance yield, or have improved operational stability or all of these characteristic and that are conveniently manufactured.

### SUMMARY OF THE INVENTION

The invention provides an OLED device comprising a cathode, an anode, and having therebetween a light emitting layer (LEL), at least one layer between the cathode and anode comprising a carbocyclic 2-aryl-9-, 10-biphenyl anthracene compound containing a total of 8-12 aromatic rings, wherein the 6-substituent is hydrogen or an alkyl group and the 2-substituent is:

(A) an unsubstituted phenyl group; or

(B) a phenyl group substituted with (a) a fluoro, a cyano, or an alkyl group or (b) a m- or p-phenyl group; or

(C) a substituted or unsubstituted fused ring aromatic group.

Alternatively, the anthracene contains no fused rings in the 9- and 10- positions and the 6-substituent is not limited as above.

The invention provides improved OLED properties such as improved drive voltage, emission efficiency and stability.

### BRIEF DESCRIPTION OF THE DRAWINGS

FIG. 1 shows a schematic cross-sectional view of an OLED device that represents one embodiment of the present invention.

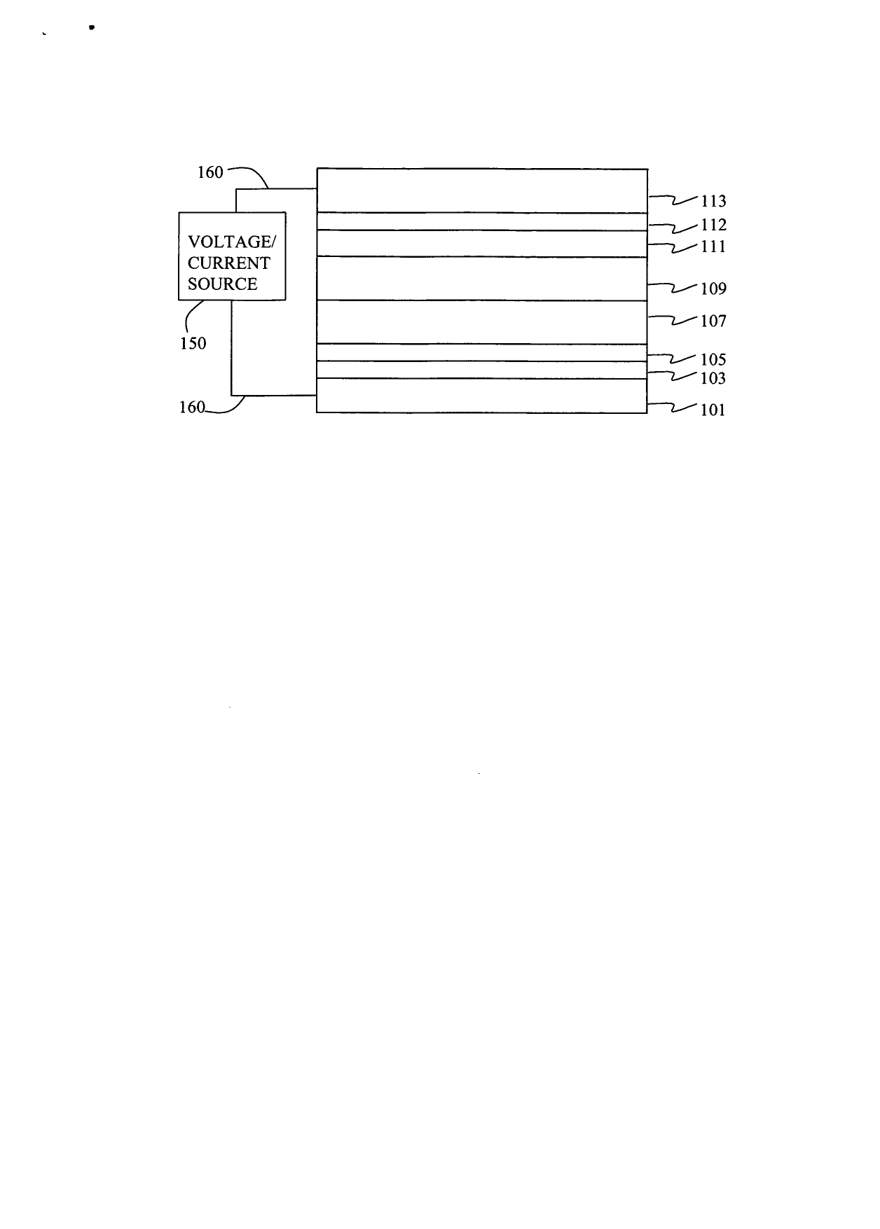

### DETAILED DESCRIPTION OF THE INVENTION

The invention is generally summarized above. The invention provides for a multilayer electroluminescent device comprising a cathode, an anode, at least one light-emitting layer (LEL). At least one layer includes a carbocyclic 2-aryl-9,10-biphenylanthracene compound, where the anthracene numbering system is shown below.

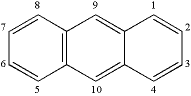

The 2-aryl-9,10-biphenylanthracene compound contains a total of 8-12 rings in order to keep the sublimation temperature in a desirable temperature range. In one embodiment, the 2-aryl-9,10-biphenylanthracene compound contains a total of 8-10 rings or even only 8-9 rings are present.

The 2-aryl substituent can be an unsubstituted phenyl group or a phenyl group substituted with a fluoro, a cyano, or alkyl group, such as a methyl or trifluoromethyl group. The 2-aryl substituent can also be a phenyl group substituted in the meta orpara position with a phenyl group, thus the 2-aryl substituent could be a p-biphenyl group or a m-biphenyl group. Alternatively, the 2-aryl substituent can be a substituted or unsubstituted fused ring aromatic group such as a naphthyl group, anthranyl group or a phenanthryl group.

The anthracene compound is substituted with biphenyl groups in the 9- and 10-positions. These groups may be the same or different. In one desirable embodiment, they are different. In another embodiment, the carbocyclic 2-aryl-9,10-biphenylanthracene includes at least one p-biphenyl group in the 9- or 10-position of the anthracene and suitably both the 9- and 10-positons may include independently selected p-biphenyl groups. In a further embodiment, the 9- and 10-positions include ap-biphenyl and an m-biphenyl group.

In one desirable embodiment, the biphenyl groups in the 9- and 10-positions do not include fused rings and in one suitable embodiment, the 9,10-biphenyl groups are not further substituted.

The anthracene nucleus is substituted in the 6-position with a hydrogen, a fluoro substituent, a cyano substituent, or an alkyl group, such as a methyl group or a t-butyl group. Desirably, the 6-position bears only a hydrogen or an alkyl group.

In another aspect of the invention, the anthracene compound is represented by Formula (1).

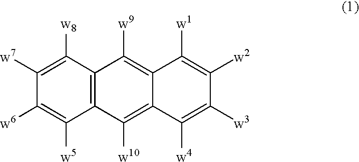

In Formula (1), w², w³, w⁴, w⁵, w⁷ and w⁸ represent hydrogen or an independently selected substituent group, such as a methyl group, phenyl group, or a naphthyl group. In the Formula, w² represents an unsubstituted phenyl group, or a phenyl group substituted with an alkyl group, a fluoro, a cyano, or fused ring aryl group. Substituent w² may also represent a phenyl group substituted with a phenyl group in the meta orpara position. In the Formula, w² may also represent a substituted or unsubstituted fused ring aromatic group, such as a naphthyl group or phenanthryl group. In Formula (1), w⁶ represents hydrogen or an alkyl group such as a methyl or t-butyl group.

In Formula (1), w⁹ and w¹⁰ represent independently selected biphenyl groups, which may be the same or different. In one desirable embodiment, they are different. In another suitable embodiment, at least one of w⁹ and w¹⁰ represents ap-biphenyl group. In a further embodiment, both w⁹ and w¹⁰ represent independently selected p-biphenyl groups. In a still further embodiment, one of w⁹ and w¹⁰ represents ap-biphenyl group and one represents an m-biphenyl group.

Materials of Formula (1) can be prepared by methods described in the literature or by variations of such methods. One useful synthetic pathway is illustrated in Scheme I.

In Scheme I, Cpd-A represents an anthracene derivative where w¹ and w³ through w⁸ have been described previously and Ar¹ represents an aryl group. With the proper choice of substituents, Cpd-A can be monobrominated, equation 1, for example by treatment with N-bromosuccinimide, to afford Cpd-B.

The next step, equation 2, involves reacting Cpd-B with an aryl boronic acid, Cpd-C. In Cpd-C, Ar² represents an aryl group, r¹ represents a substituent, and n is 0-5. This reaction is a palladium catalyzed coupling. For examples of this type of coupling reaction, see J. Hassan, M. Sevignon, C. Gozzi, E. Schulz, M. Lemaire, Marc, Chem. Rev, 102, 1359 (2002) and references cited therein and A. F. Litthe, C. Dai, and G. C. Fu, J. Am. Chem. Soc., 122, 4020 (2000).

The product formed in the equation 2 coupling reaction, Cpd-D, can be brominated (equation 3). The resulting bromo compound (Cpd-E) can be subjected to another coupling reaction (equation 4) with a boronic acid derivative, Cpd-F, where Ar³ represents an aryl group, r² represents a substituent, and m is 0-5. The final product, Cpd-G, is a material of Formula (1).

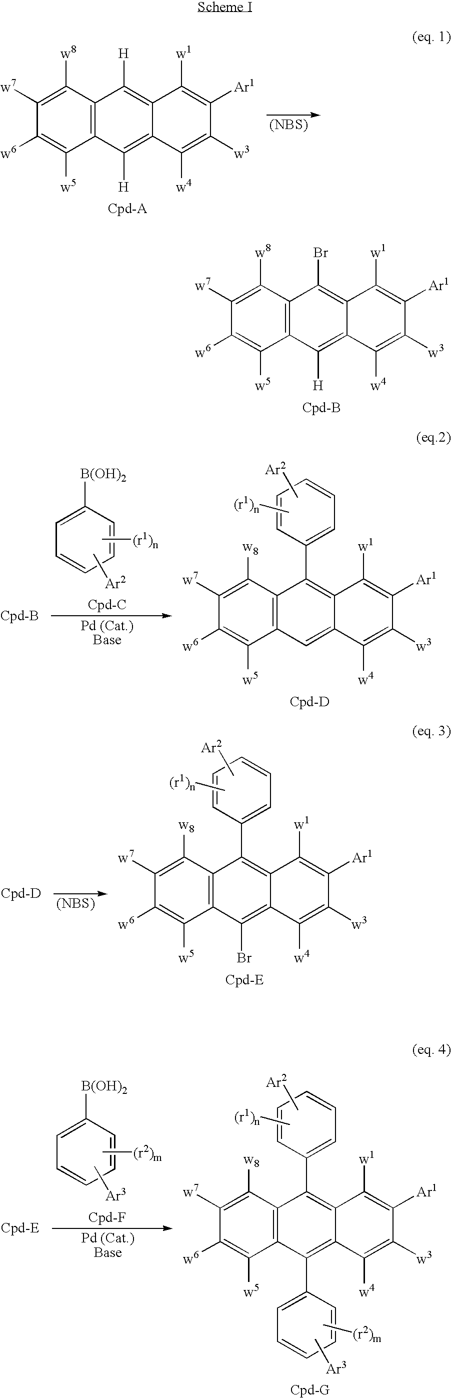

Illustrative examples of compounds of Formula (1) are listed below.

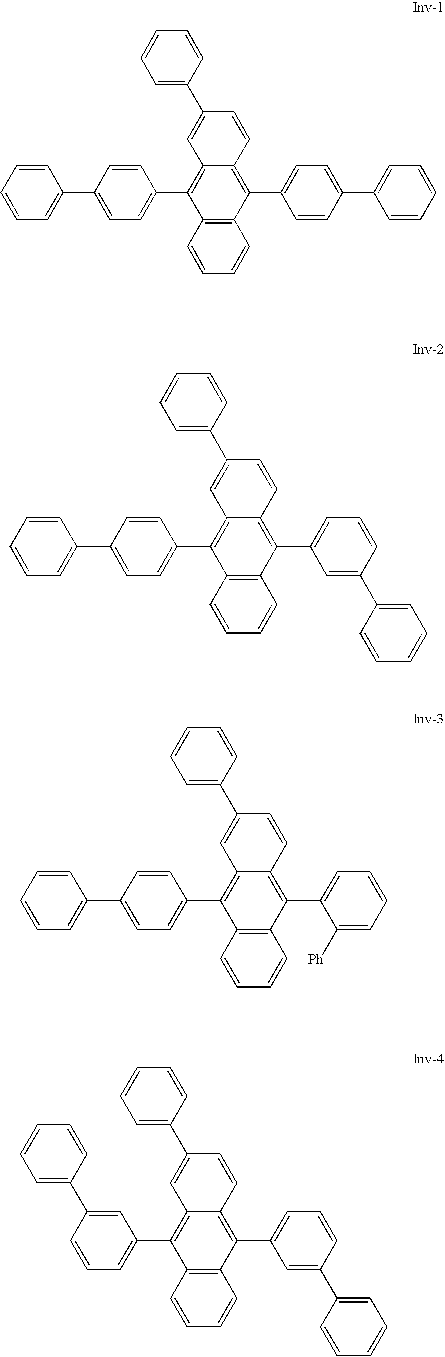

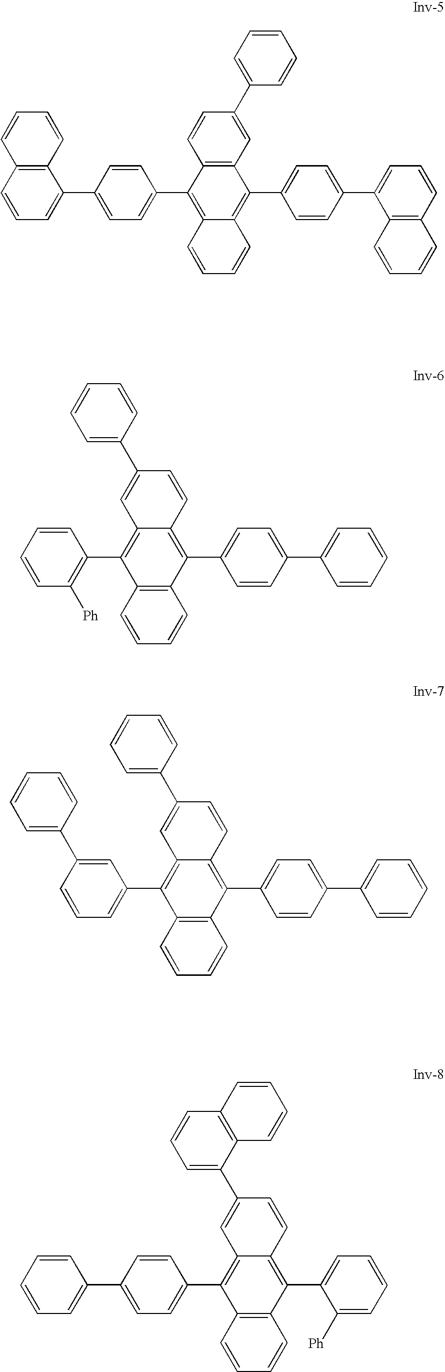

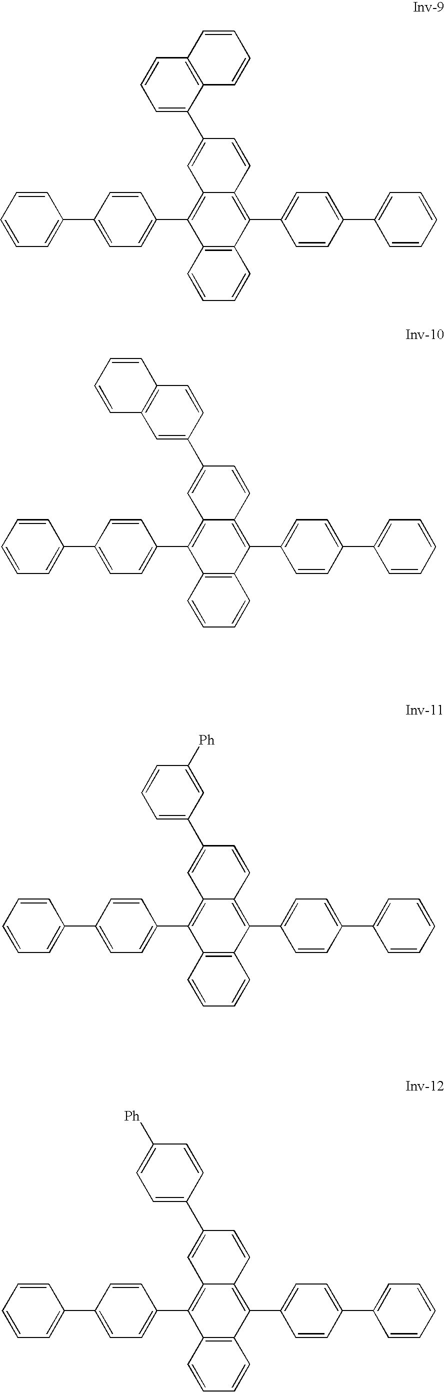

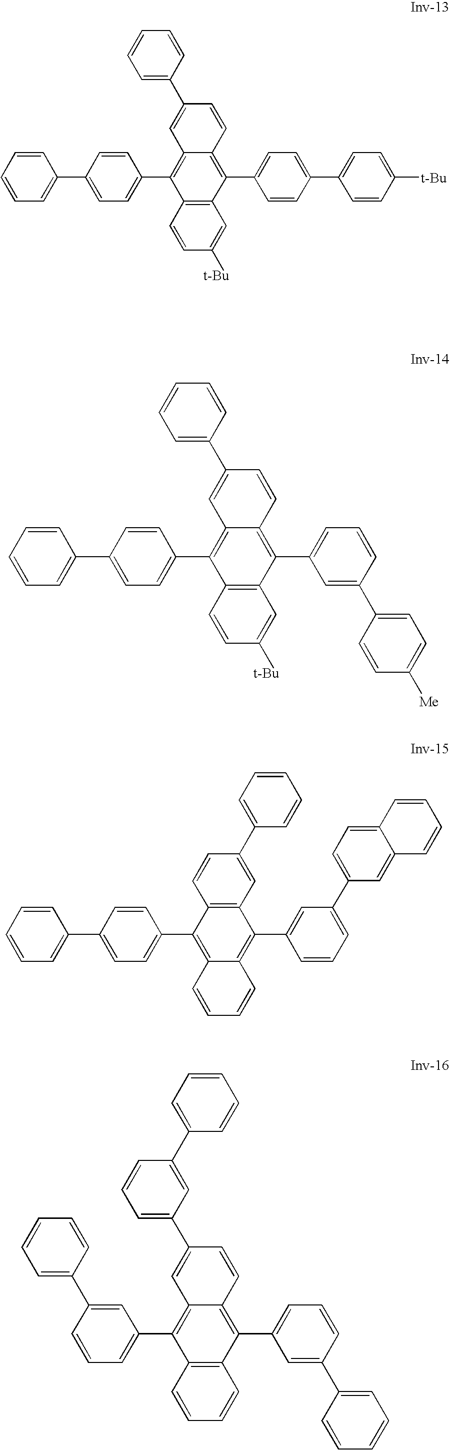

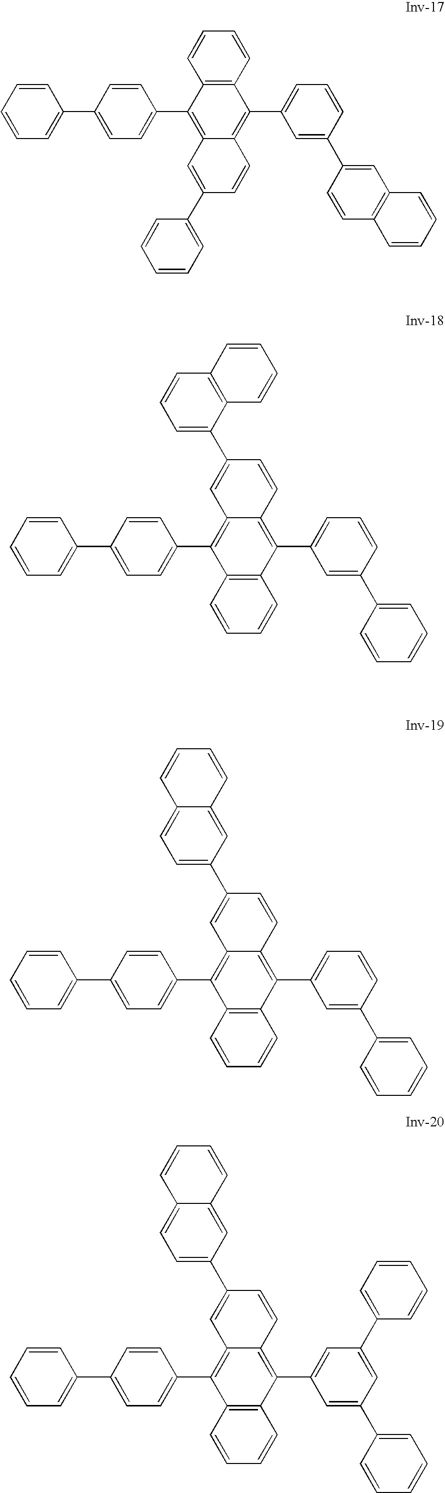

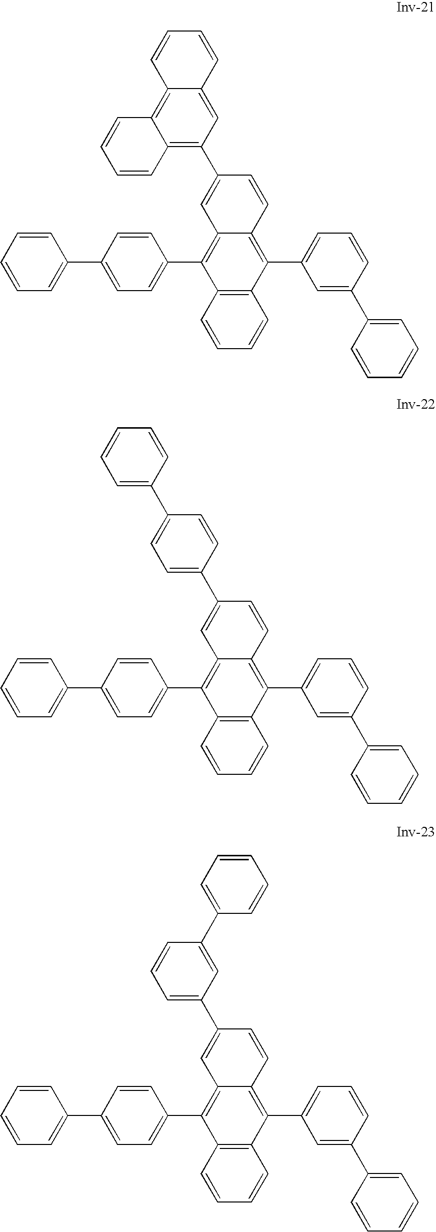

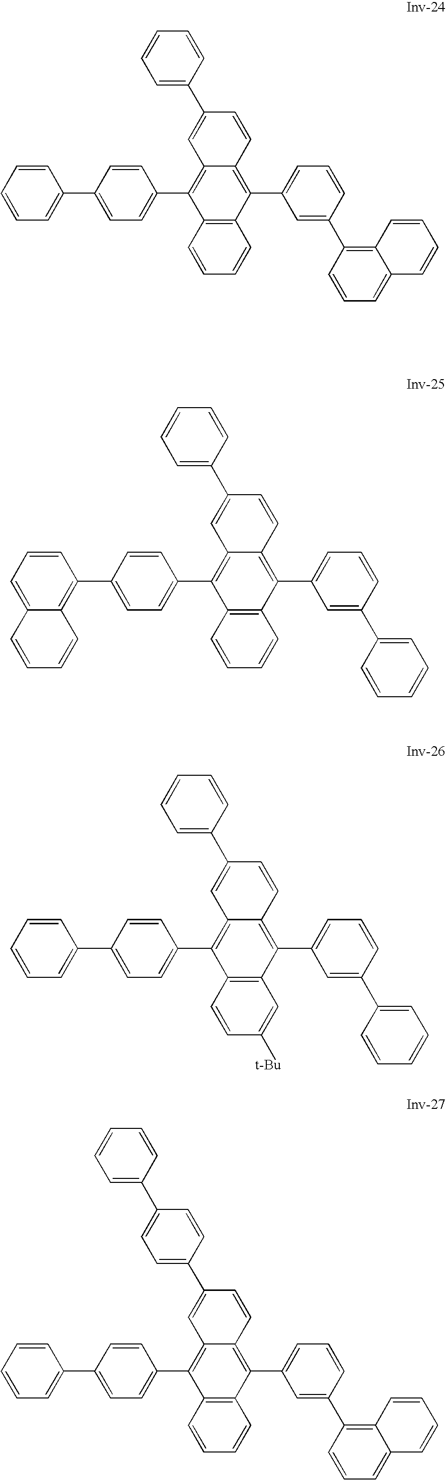

Unless otherwise specifically stated, use of the term “substituted” or “substituent” means any group or atom other than hydrogen. Additionally, unless otherwise specifically stated, when a compound with a substitutable hydrogen is identified or the term “group” is used, it is intended to encompass not only the substituent's unsubstituted form, but also its form further substituted with any substituent group or groups as herein mentioned, so long as the substituent does not destroy properties necessary for device utility. Suitably, a substituent group may be halogen or may be bonded to the remainder of the molecule by an atom of carbon, silicon, oxygen, nitrogen, phosphorous, sulfur, selenium, or boron. The substituent may be, for example, halogen, such as chloro, bromo or fluoro; nitro; hydroxyl; cyano; carboxyl; or groups which may be further substituted, such as alkyl, including straight or branched chain or cyclic alkyl, such as methyl, trifluoromethyl, ethyl, t-butyl, 3-(2,4-di-t-pentylphenoxy) propyl, and tetradecyl; alkenyl, such as ethylene, 2-butene; alkoxy, such as methoxy, ethoxy, propoxy, butoxy, 2-methoxyethoxy, sec-butoxy, hexyloxy, 2-ethylhexyloxy, tetradecyloxy, 2-(2,4-di-t-pentylphenoxy)ethoxy, and 2-dodecyloxyethoxy; aryl such as phenyl, 4-t-butylphenyl, 2,4,6-trimethylphenyl, naphthyl; aryloxy, such as phenoxy, 2-methylphenoxy, alpha- or beta-naphthyloxy, and 4-tolyloxy; carbonamido, such as acetamido, benzamido, butyramido, tetradecanamido, alpha-(2,4-di-t-pentyl-phenoxy)acetamido, alpha-(2,4-di-t-pentylphenoxy)butyramido, alpha-(3-pentadecylphenoxy)-hexanamido, alpha-(4-hydroxy-3-t-butylphenoxy)-tetradecanamido, 2-oxo-pyrrolidin-1-yl, 2-oxo-5-tetradecylpyrrolin-1-yl, N-methyltetradecanamido, N-succinimido, N-phthalimido, 2,5-dioxo- 1-oxazolidinyl, 3-dodecyl-2,5-dioxo-1-imidazolyl, and N-acetyl-N-dodecylamino, ethoxycarbonylamino, phenoxycarbonylamino, benzyloxycarbonylamino, hexadecyloxycarbonylamino, 2,4-di-t-butylphenoxycarbonylamino, phenylcarbonylamino, 2,5-(di-t-pentylphenyl)carbonylamino, p-dodecyl-phenylcarbonylamino, p-tolylcarbonylamino, N-methylureido, N,N-dimethylureido, N-methyl-N-dodecylureido, N-hexadecylureido, N,N-dioctadecylureido, N,N-dioctyl-N′-ethylureido, N-phenylureido, N,N-diphenylureido, N-phenyl-N-p-tolylureido, N-(m-hexadecylphenyl)ureido, N,N-(2,5-di-t-pentylphenyl)-N′-ethylureido, and t-butylcarbonamido; sulfonamido, such as methylsulfonamido, benzenesulfonamido, p-tolylsulfonamido, p-dodecylbenzenesulfonamido, N-methyltetradecylsulfonamido, N,N-dipropyl- sulfamoylamino, and hexadecylsulfonamido; sulfamoyl, such as N-methylsulfamoyl, N-ethylsulfamoyl, N,N-dipropylsulfamoyl, N-hexadecylsulfamoyl, N,N-dimethylsulfamoyl, N-[3-(dodecyloxy)propyl]sulfamoyl, N-[4-(2,4-di-t-pentylphenoxy)butyl]sulfamoyl, N-methyl-N-tetradecylsulfamoyl, s and N-dodecylsulfamoyl; carbamoyl, such as N-methylcarbamoyl, N,N-dibutylcarbamoyl, N-octadecylcarbamoyl, N-[4-(2,4-di-t-pentylphenoxy)butyl]carbamoyl, N-methyl-N-tetradecylcarbamoyl, and N,N-dioctylcarbamoyl; acyl, such as acetyl, (2,4-di-t-amylphenoxy)acetyl, phenoxycarbonyl, p-dodecyloxyphenoxycarbonyl methoxycarbonyl, butoxycarbonyl, tetradecyloxycarbonyl, ethoxycarbonyl, benzyloxycarbonyl, 3-pentadecyloxycarbonyl, and dodecyloxycarbonyl; sulfonyl, such as methoxysulfonyl, octyloxysulfonyl, tetradecyloxysulfonyl, 2-ethylhexyloxysulfonyl, phenoxysulfonyl, 2,4-di-t-pentylphenoxysulfonyl, methylsulfonyl, octylsulfonyl, 2-ethylhexylsulfonyl, dodecylsulfonyl, hexadecylsulfonyl, phenylsulfonyl, 4-nonylphenylsulfonyl, and p-tolylsulfonyl; sulfonyloxy, such as dodecylsulfonyloxy, and hexadecylsulfonyloxy; sulfinyl, such as methylsulfinyl, octylsulfinyl, 2-ethylhexylsulfinyl, dodecylsulfinyl, hexadecylsulfinyl, phenylsulfinyl, 4-nonylphenylsulfinyl, andp-tolylsulfinyl; thio, such as ethylthio, octylthio, benzylthio, tetradecylthio, 2-(2,4-di-t-pentylphenoxy)ethylthio, phenylthio, 2-butoxy-5-t-octylphenylthio, and p-tolylthio; acyloxy, such as acetyloxy, benzoyloxy, octadecanoyloxy, p-dodecylamidobenzoyloxy, N-phenylcarbamoyloxy, N-ethylcarbamoyloxy, and cyclohexylcarbonyloxy; amine, such as phenylanilino, 2-chloroanilino, diethylamine, dodecylamine; imino, such as 1 (N-phenylimido)ethyl, N-succinimido or 3-benzylhydantoinyl; phosphate, such as dimethylphosphate and ethylbutylphosphate; phosphite, such as diethyl and dihexylphosphite; a heterocyclic group, a heterocyclic oxy group or a heterocyclic thio group, each of which may be substituted and which contain a 3 to 7 membered heterocyclic ring composed of carbon atoms and at least one hetero atom selected from the group consisting of oxygen, nitrogen, sulfur, phosphorous, or boron. Such as 2-furyl, 2- thienyl, 2-benzimidazolyloxy or 2-benzothiazolyl; quaternary ammonium, such as triethylammonium; quaternary phosphonium, such as triphenylphosphonium; and silyloxy, such as trimethylsilyloxy.

If desired, the substituents may themselves be further substituted one or more times with the described substituent groups. The particular substituents used may be selected by those skilled in the art to attain desirable properties for a specific application and can include, for example, electron-withdrawing groups, electron-donating groups, and steric groups. When a molecule may have two or more substituents, the substituents may be joined together to form a ring such as a fused ring unless otherwise provided. Generally, the above groups and substituents thereof may include those having up to 48 carbon atoms, typically 1 to 36 carbon atoms and usually less than 24 carbon atoms, but greater numbers are possible depending on the particular substituents selected.

For the purpose of this invention, also included in the definition of a heterocyclic ring are those rings that include coordinate or dative bonds. The definition of a coordinate bond can be found in Grant & Hackh's Chemical Dictionary, page 91. In essence, a coordinate bond is formed when electron rich atoms such as O or N, donate a pair of electrons to electron deficient atoms such as Al or B.

It is well within the skill of the art to determine whether a particular group is electron donating or electron accepting. The most common measure of electron donating and accepting properties is in terms of Hammett σ values. Hydrogen has a Hammett σ value of zero, while electron donating groups have negative Hammett σ values and electron accepting groups have positive Hammett σ values. Lange's handbook of Chemistry, 12^{th} Ed., McGraw Hill, 1979, Table 3-12, pp. 3-134 to 3-138, here incorporated by reference, lists Hammett σ values for a large number of commonly encountered groups. Hammett σ values are assigned based on phenyl ring substitution, but they provide a practical guide for qualitatively selecting electron donating and accepting groups.

Suitable electron donating groups may be selected from —R′, —OR′, and —NR′(R″) where R′ is a hydrocarbon containing up to 6 carbon atoms and R″ is hydrogen or R′. Specific examples of electron donating groups include methyl, ethyl, phenyl, methoxy, ethoxy, phenoxy, —N(CH₃)₂, —N(CH₂CH₃)₂, —NHCH₃, —N(C₆H₅)₂, —N(CH₃)(C₆H₅), and —NHC₆H₅.

Suitable electron accepting groups may be selected from the group consisting of cyano, α-haloalkyl, α-haloalkoxy, amido, sulfonyl, carbonyl, carbonyloxy and oxycarbonyl substituents containing up to 10 carbon atoms. Specific examples include —CN, —F, —CF₃, —OCF₃, —CONHC₆H₅, —SO₂C₆H₅, —COC₆H₅, —CO₂C₆H₅, and —OCOC₆H₅.

In one desirable embodiment, the anthracene material is in a layer that includes one or more light-emitting materials. Suitably, the anthracene material comprises the host material of the light-emitting layer. In addition to the anthracene host material, there may be one or more co-hosts present in the layer.

In one embodiment, a co-host is present that is a hole-transporting material. For example the co-host may be a tertiary amine or a mixture of such compounds. Examples of useful hole-transporting co-host materials are 4,4′-bis[N-(1-naphthyl)-N-phenylamino]biphenyl (NPB), and 4,4′-bis[N-(1-naphthyl)-N-(2-naphthyl)amino]biphenyl (TNB).

In another embodiment, a co-host that is an electron-transporting material is present. Metal complexes of 8-hydroxyquinoline and similar derivatives, also known as metal-chelated oxinoid compounds, constitute a class of useful co-host compounds. A useful example of electron-transporting co-host material is tris(8-quinolinolato)aluminum(III) (AlQ).

When present, the co-host is often at a level of 1-50% of the layer, frequently at 1-20% of the layer, and commonly at a level of 5-15% of the layer by volume.

The LEL includes a light-emitting material(s) which is desirably present in an amount of up to 15% of the light-emitting layer by volume, commonly 0.1-10% and more typically from 0.5-8.0% of the layer by volume.

An important relationship for choosing a light-emitting fluorescent material for use with a host is a comparison of the excited singlet-state energies of the host and the fluorescent material. It is highly desirable that the excited singlet-state energy of the light-emitting material be lower than that of the host material. The excited singlet-state energy is defined as the difference in energy between the emitting singlet state and the ground state. For non-emissive hosts, the lowest excited state of the same electronic spin as the ground state is considered the emitting state.

The layer may emit light ranging from blue to red depending on the nature of the light-emitting material. Blue light is generally defined as having a wavelength range in the visible region of the electromagnetic spectrum of 450-480 nm, blue-green 480-510 nm, green 510-550, green-yellow 550-570 nm, yellow 570-590 nm, orange 590-630 nm and red 630-700 nm, as defined by R. W. Hunt, The Reproduction of Colour in Photography, Printing & Television, 4^{th} Edition 1987, Fountain Press. Suitable combinations of these components produce white light.

Anthracene materials of Formula (1) may be especially useful hosts for blue or blue-green materials. Many materials that emit blue or blue-green light are known in the art and are contemplated for use in the practice of the present invention. Particularly useful classes of blue emitters include perylene and its derivatives such as a perylene nucleus bearing one or more substituents such as an alkyl group or an aryl group. A desirable perylene derivative for use as an emitting material is 2,5,8,11-tetra-t-butylperylene.

Another useful class of fluorescent materials includes blue or blue-green light emitting derivatives of distyrylarenes, such as distyrylbenzene and distyrylbiphenyl, including compounds described in U.S. Pat. No. 5,121,029. Among derivatives of distyrylarenes that provide blue or blue-green luminescence, particularly useful are those substituted with diarylamino groups, also known as distyrylamines. Examples include Formula (2a), listed below, wherein Ar₁, each Ar₂, and Ar₃ through Ar₈ are independently selected aryl or heteroaryl groups, which may contain additional fused rings and provided that two aryl or heteroaryl rings may be joined by ring fusion, m is 0 or 1. In one embodiment, Ar₁, each Ar₂, and Ar₃ through Ar₈ represent phenylene or phenyl groups.

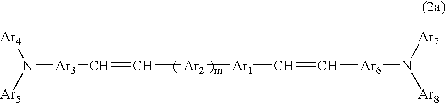

Illustrative examples of useful distyrylamines are blue or blue green emitters listed below.

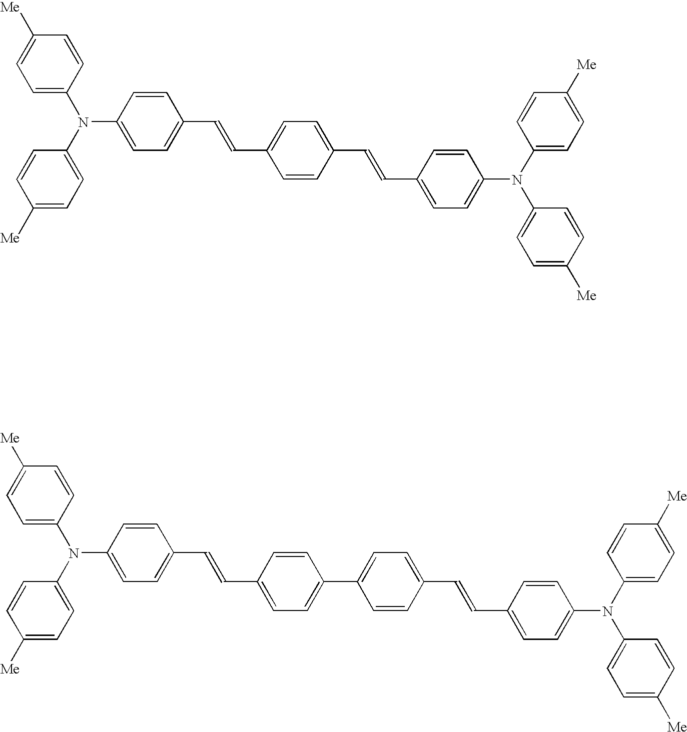

Commonly assigned Ser. No. 10/977,839, filed Oct. 29, 2004 entitled Organic Element for Electroluminescent Devices by Margaret J. Helber, et al., which is incorporated herein by reference, describes additional useful blue and blue-green light-emitting materials, such as the material listed below.

In one embodiment the light-emitting material is represented by Formula (2b).

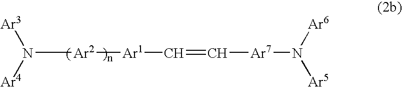

In Formula (2b), Ar¹ through Ar⁶ are independently selected aryl groups and may each represent phenyl groups, fused aromatic rings such as naphthyl, anthranyl or phenanthryl, heterocyclic aromatic rings wherein one or more carbon atoms have replaced by nitrogen, oxygen or sulfur, and monovalently linked aromatic rings such as biphenyl, and Ar¹ through Ar⁶ may be unsubstituted or further substituted in those ring positions bearing hydrogens. Additionally Ar³ and Ar⁴ may be joined directly or through additional atoms to form a carbocyclic or heterocyclic ring. Ar⁵ and Ar⁶ may be joined directly or through additional atoms to form a carbocyclic or heterocyclic ring. Ar⁷ is phenyl, a fused ring aromatic carbocyclic group or a heterocyclic group. Ar⁷ may be unsubstituted or further substituted in those ring positions bearing hydrogens. In the Formula, n is 1, 2, or 3. Illustrative examples of useful materials are shown below.

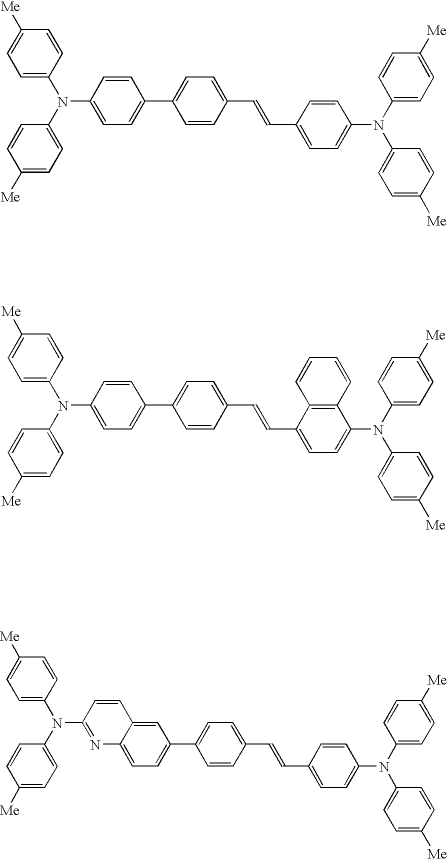

Another useful class of emitters comprise a boron atom. Desirable light-emitting materials that contain boron include those described in US 2003/0198829, US 2003/0201415 and US 2005/0170204, which are incorporated herein by reference. Suitable light-emitting materials, including those that emit blue or blue-green light, are represented by the structure Formula (3).

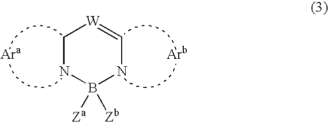

In Formula (3), Ar^{a} and Ar^{b} independently represent the atoms necessary to form a five or six-membered aromatic ring group, such as a pyridine group. Z^{a} and Z^{b} represent independently selected substituents, such as fluoro substituents. In Formula (3), w represents N or C-Y, wherein Y represents hydrogen or a substituent, such as an aromatic group, such as a phenyl group or a tolyl group, an alkyl group, such as a methyl group, a cyano substituent, or a trifluoromethyl substituent.

Illustrative examples of useful boron-containing fluorescent materials are listed below.

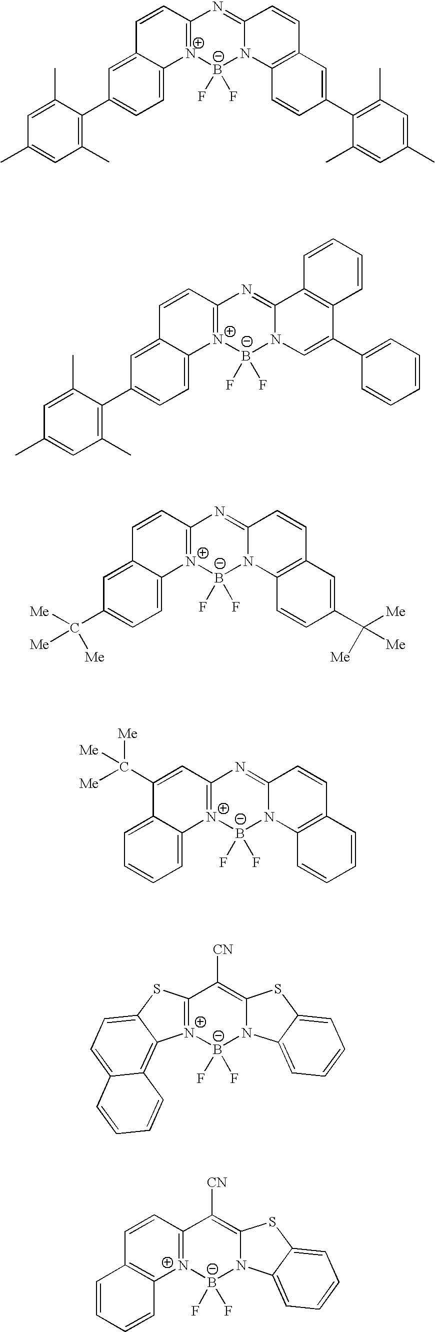

A particularly useful class of green light-emitting material includes quinacridone compounds. Useful quinacridones are described US 2004/0001969, U.S. Pat. No. 6,664,396, U.S. Pat. No. 5,593,788, and JP 09-13026. In one embodiment, the light-emitting material in the light-emitting layer is a quinacridone compound represented by Formula (4).

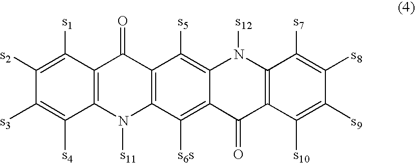

In Formula (4), s₁-s₁₀ independently represent hydrogen or an independently selected substituent, such as a phenyl group, a tolyl group, a halogen such as F, or an alkyl group, such as a methyl group. Adjacent substituents may combine to form rings, such as fused benzene ring groups.

In Formula (4), s₁₁ and S12 independently represent an alkyl group or an aromatic group. In one suitable embodiment, s₁₁ and S₁₂ independently represent a phenyl ring group, such as a phenyl ring or a tolyl ring.

Illustrative examples of useful quinacridone compounds are shown below.

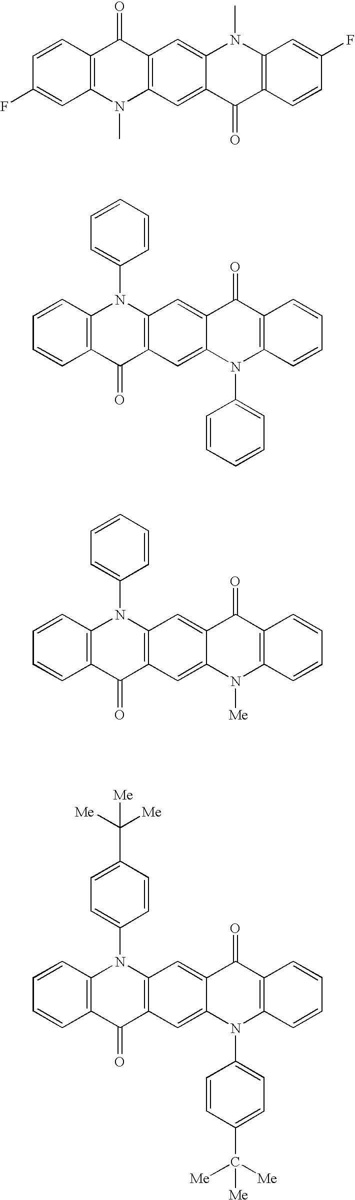

Another particularly useful class of green light-emitting materials includes coumarin compounds. For example, useful coumarins are described in Tang et al., U.S. Pat. No. 4,769,292 and U.S. Pat. No. 6,020,078. In one embodiment of the invention, the third material in the light-emitting layer is a coumarin represented by Formula (5).

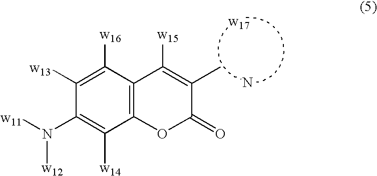

In Formula (5), W₁₁ and w₁₂ represent an independently selected substituent, such as an alkyl group or aryl group, provided w₁₁ and w₁₂ may combine with each other or with W₁₃ and W₁₄ to form rings. Desirably w₁₁ and W12 represent independently selected alkyl groups, provided w₁₁ and W₁₂ may combine with each other or with W₁₃ and W₁₄ to form saturated rings. In Formula (5), W13-W16 independently represent hydrogen or an independently selected substituent, such as phenyl ring group or a methyl group. Adjacent substituents may combine to form rings, such as fused benzene rings. In Formula (5), W₁₇ represents the atoms necessary to complete a heteroaromatic ring, such as a benzothiazole ring group. Illustrative examples of useful coumarin compounds are shown below.

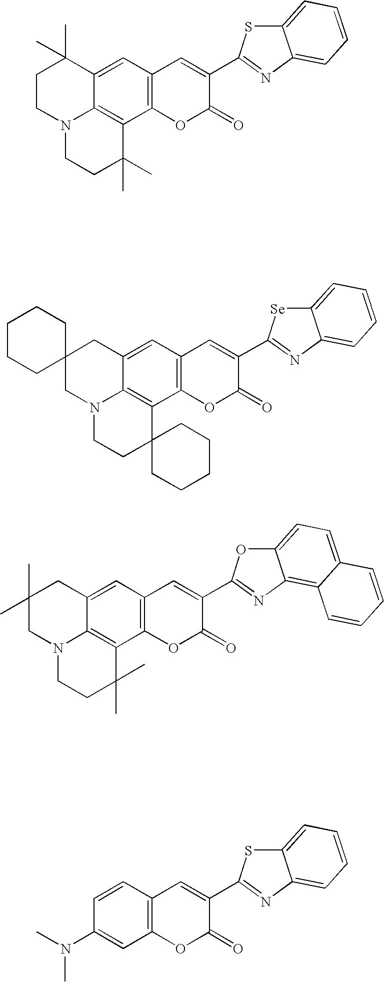

Examples of additional useful emitting materials include derivatives of anthracene, fluorene, periflanthene, and indenoperylene.

In one embodiment, one layer including a carbocyclic 2-aryl-9,10-biphenylanthracene compound, emits blue or blue-green light and an additional layer emits yellow or red light and contains a of rubrene derivative.

In another embodiment of the invention, when additional layers are present so that the emitted light is white, a filter capable of controlling the spectral components of the white light such as red, green and blue, can be placed over-lying the device to give a device useful for color display.

General Device Architecture

The present invention can be employed in many OLED device configurations using small molecule materials, oligomeric materials, polymeric materials, or combinations thereof. These include very simple structures comprising a single anode and cathode to more complex devices, such as passive matrix displays comprised of orthogonal arrays of anodes and cathodes to form pixels, and active-matrix displays where each pixel is controlled independently, for example, with thin film transistors (TFTs).

There are numerous configurations of the organic layers wherein the present invention can be successfully practiced. The essential requirements of an OLED are an anode, a cathode, and an organic light-emitting layer located between the anode and cathode. Additional layers may be employed as more fully described hereafter.

A typical structure, especially useful for of a small molecule device, is shown in the Figure and is comprised of a substrate 101, an anode 103, a hole-injecting layer 105, a hole-transporting layer 107, a light-emitting layer 109, an electron-transporting layer 111, an electron-injecting layer 112, and a cathode 113. These layers are described in detail below. Note that the substrate may alternatively be located adjacent to the cathode, or the substrate may actually constitute the anode or cathode. The organic layers between the anode and cathode are conveniently referred to as the organic EL element. Also, the total combined thickness of the organic layers is desirably less than 500 nm.

The anode and cathode of the OLED are connected to a voltage/current source 150 through electrical conductors 160. The OLED is operated by applying a potential between the anode and cathode such that the anode is at a more positive potential than the cathode. Holes are injected into the organic EL element from the anode and electrons are injected into the organic EL element at the cathode. Enhanced device stability can sometimes be achieved when the OLED is operated in an AC mode where, for some time period in the cycle, the potential bias is reversed and no current flows. An example of an AC driven OLED is described in U.S. Pat. No. 5,552,678.

Substrate

The OLED device of this invention is typically provided over a supporting substrate 101 where either the cathode or anode can be in contact with the substrate. The substrate can be a complex structure comprising multiple layers of materials. This is typically the case for active matrix substrates wherein TFTs are provided below the OLED layers. It is still necessary that the substrate, at least in the emissive pixilated areas, be comprised of largely transparent materials. The electrode in contact with the substrate is conveniently referred to as the bottom electrode. Conventionally, the bottom electrode is the anode, but this invention is not limited to that configuration. The substrate can either be light transmissive or opaque, depending on the intended direction of light emission. The light transmissive property is desirable for viewing the EL emission through the substrate. Transparent glass or plastic is commonly employed in such cases. For applications where the EL emission is viewed through the top electrode, the transmissive characteristic of the bottom support can be light transmissive, light absorbing or light reflective. Substrates for use in this case include, but are not limited to, glass, plastic, semiconductor materials, silicon, ceramics, and circuit board materials. It is necessary to provide in these device configurations a light-transparent top electrode.

Anode When the desired electroluminescent light emission (EL) is viewed through anode, the anode should be transparent or substantially transparent to the emission of interest. Common transparent anode materials used in this invention are indium-tin oxide (ITO), indium-zinc oxide (IZO) and tin oxide, but other metal oxides can work including, but not limited to, aluminum- or indium-doped zinc oxide, magnesium-indium oxide, and nickel-tungsten oxide. In addition to these oxides, metal nitrides, such as gallium nitride, and metal selenides, such as zinc selenide, and metal sulfides, such as zinc sulfide, can be used as the anode. For applications where EL emission is viewed only through the cathode, the transmissive characteristics of the anode are immaterial and any conductive material can be used, transparent, opaque or reflective. Example conductors for this application include, but are not limited to, gold, iridium, molybdenum, palladium, and platinum. Typical anode materials, transmissive or otherwise, have a work function of 4.1 eV or greater. Desired anode materials are commonly deposited by any suitable means such as evaporation, sputtering, chemical vapor deposition, or electrochemical means. Anodes can be patterned using well-known photolithographic processes. Optionally, anodes may be polished prior to application of other layers to reduce surface roughness so as to minimize shorts or enhance reflectivity.

Hole-Injecting Layer (HIL)

While not always necessary, it is often useful that a hole-injecting layer 105 be provided between anode 103 and hole-transporting layer 107. The hole-injecting material can serve to improve the film formation property of subsequent organic layers and to facilitate injection of holes into the hole-transporting layer. Suitable materials for use in the hole-injecting layer include, but are not limited to, porphyrinic compounds as described in U.S. Pat. No. 4,720,432, plasma-deposited fluorocarbon polymers as described in U.S. Pat. No. 6,208,075, and some aromatic amines, for example, m-MTDATA (4,4′,4″-tris[(3-methylphenyl)phenylamino]triphenylamine). Alternative hole-injecting materials reportedly useful in organic EL devices are described in EP 0891121 and EP 1029909.

Additional useful hole-injecting materials are described in U.S. Pat. No. 6,720,573. For example, the material below may be useful for such purposes. 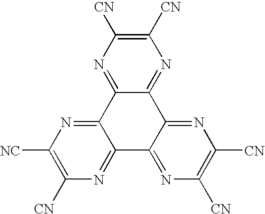
Hole-Transporting Layer (HTL)

The hole-transporting layer 107 of the organic EL device contains at least one hole-transporting compound, such as an aromatic tertiary amine, where the latter is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel et al. U.S. Pat. No. 3,180,730. Other suitable triarylamines substituted with one or more vinyl radicals and/or comprising at least one active hydrogen containing group are disclosed by Brantley et al U.S. Pat. No. 3,567,450 and U.S. Pt. No. 3,658,520.

A more preferred class of aromatic tertiary amines are those which include at least two aromatic tertiary amine moieties as described in U.S. Pat. No. 4,720,432 and U.S. Pat. No. 5,061,569. Such compounds include those represented by structural Formula (A).

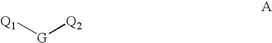

In Formula (A), Q₁ and Q₂ are independently selected aromatic tertiary amine moieties and G is a linking group such as an arylene, cycloalkylene, or alkylene group of a carbon to carbon bond. In one embodiment, at least one of Q₁ or Q₂ contains a polycyclic fused ring structure, e.g., a naphthalene. When G is an aryl group, it is conveniently a phenylene, biphenylene, or naphthalenediyl moiety.

A useful class of triarylamines satisfying structural Formula (A) and containing two triarylamine moieties is represented by structural Formula (B):

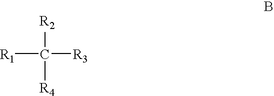

In Formula (B), R₁ and R₂ each independently represents a hydrogen atom, an aryl group, or an alkyl group or R₁ and R₂ together represent the atoms completing a cycloalkyl group; and

R₃ and R₄ each independently represents an aryl group, which is in turn substituted with a diaryl substituted amino group, as indicated by structural Formula (C):

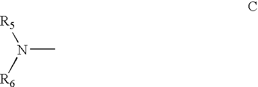

wherein R₅ and R₆ are independently selected aryl groups. In one embodiment, at least one of R₅ or R₆ contains a polycyclic fused ring structure, e.g., a naphthalene.

Another class of aromatic tertiary amines are the tetraaryldiamines. Desirable tetraaryldiamines include two diarylamino groups, such as indicated by Formula (C), linked through an arylene group. Useful tetraaryldiamines include those represented by Formula (D).

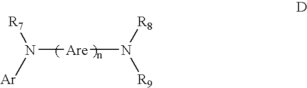

In Formula (D), each Are is an independently selected arylene group, such as a phenylene, naphthylenediyl or anthracenediyl moiety,

n is an integer of from 6b 1 to 4, and

Ar, R₇, R₈, and R₉ are independently selected aryl groups.

In a typical embodiment, at least one of Ar, R₇, R₈, and R₉ is a polycyclic fused ring structure, e.g., a naphthalene.

The various alkyl, alkylene, aryl, and arylene moieties of the foregoing structural Formulae (A), (B), (C), (D), can each in turn be substituted. Typical substituents include alkyl groups, alkoxy groups, aryl groups, aryloxy groups, benzo and halogen such as fluoride. The various alkyl and alkylene moieties typically contain from about 1 to 6 carbon atoms. The cycloalkyl moieties can contain from 3 to about 10 carbon atoms, but typically contain five, six, or seven ring carbon atoms—e.g., cyclopentyl, cyclohexyl, and cycloheptyl ring structures. The aryl and arylene moieties are usually phenyl and phenylene moieties.

The hole-transporting layer can be formed of a single or a mixture of aromatic tertiary amine compounds. Specifically, one may employ a triarylamine, such as a triarylamine satisfying the Formula (B), in combination with a tetraaryldiamine, such as indicated by Formula (D). When a triarylamine is employed in combination with a tetraarvldiamine, the latter is positioned as a layer interposed between the triarylamine and the electron injecting and transporting layer. Illustrative of useful aromatic tertiary amines are the following:

1,1-Bis(4-di-p-tolylaminophenyl)cyclohexane (TAPC)

1,1-Bis(4-di-p-tolylaminophenyl)-4-phenylcyclohexane

4,4′-Bis(diphenylamino)quadriphenyl

Bis(4-dimethylamino-2-methylphenyl)-phenylmethane

N,N,N-Tri(p-tolyl)amine

4-(di-p-tolylamino)-4′-[4(di-p-tolylamino)-styryl]stilbene

N,N,N′,N′-Tetra-p-tolyl-4-4′-diaminobiphenyl

N,N,N′,N′-Tetraphenyl-4,4′-diaminobiphenyl

N,N,N′,N′-tetra- 1-naphthyl-4,4′-diaminobiphenyl

N,N,N′,N′-tetra-2-naphthyl-4,4′-diaminobiphenyl

N-Phenylcarbazole

4,4′-Bis[N-( 1-naphthyl)-N-phenylamino]biphenyl

4,4′-Bis[N-(1-naphthyl)-N-(2-naphthyl)amino]biphenyl

4,4″-Bis[N-(1-naphthyl)-N-phenylamino]p-terphenyl

4,4′-Bis[N-(2-naphthyl)-N-phenylamino]biphenyl

4,4′-Bis[N-(3-acenaphthenyl)-N-phenylamino]biphenyl

1,5-Bis[N-(1-naphthyl)-N-phenylamino]naphthalene

4,4′-Bis[N-(9-anthryl)-N-phenylamino]biphenyl

4,4″-Bis[N-(1-anthryl)-N-phenylamino]-p-terphenyl

4,4′-Bis[N-(2-phenanthryl)-N-phenylamino]biphenyl

4,4′-Bis[N-(8-fluoranthenyl)-N-phenylamino]biphenyl

4,4′-Bis[N-(2-pyrenyl)-N-phenylamino]biphenyl

4,4′-Bis[N-(2-naphthacenyl)-N-phenylamino]biphenyl

4,4′-Bis[N-(2-perylenyl)-N-phenylamino]biphenyl

4,4′-Bis[N-(1-coronenyl)-N-phenylamino]biphenyl

2,6-Bis(di-p-tolylamino)naphthalene

2,6-Bis[di-(1-naphthyl)amino]naphthalene

2,6-Bis[N-(1-naphthyl)-N-(2-naphthyl)amino]naphthalene

N,N,N′,N′-Tetra(2-naphthyl)-4,4″-diamino-p-terphenyl

4,4′-Bis {N-phenyl-N-[4-(1-naphthyl)-phenyl]amino}biphenyl

4,4′-Bis[N-phenyl-N-(2-pyrenyl)amino]biphenyl

2,6-Bis[N,N-di(2-naphthyl)amine]fluorene

1,5-Bis[N-(1-naphthyl)-N-phenylamino]naphthalene

4,4′,4″-tris[(3-methylphenyl)phenylamino]triphenylamine

Another class of useful hole-transporting materials includes polycyclic aromatic compounds as described in EP 1 009 041. Tertiary aromatic amines with more than two amine groups may be used including oligomeric materials. In addition, polymeric hole-transporting materials can be used such as poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS.

Light-Emitting Layer (LEL)

Useful embodiments of the light-emitting layer have been described previously. More than one light-emitting layer may be present.

As more fully described in U.S. Pat. Nos. 4,769,292 and 5,935,721, the light-emitting layer (LEL) of the organic EL element includes a luminescent fluorescent or phosphorescent material where electroluminescence is produced as a result of electron-hole pair recombination in this region. The light-emitting layer can be comprised of a single material, but more commonly consists of a host material doped with a guest emitting material or materials where light emission comes primarily from the emitting materials and can be of any color. Desirable host materials have been described previously. Additional host materials in the light-emitting layer can be an electron-transporting material, as defined below, a hole-transporting material, as defined above, or another material or combination of materials that support hole-electron recombination. The emitting material is usually chosen from highly fluorescent dyes and phosphorescent compounds, e.g., transition metal complexes as described in WO 98/55561, WO 00/18851, WO 00/57676, and WO 00/70655. Emitting materials are typically incorporated at 0.01 to 10% by weight of the host material.

The host and emitting materials can be small non-polymeric molecules or polymeric materials such as polyfluorenes and polyvinylarylenes (e.g., poly(p-phenylenevinylene), PPV). In the case of polymers, small molecule emitting materials can be molecularly dispersed into a polymeric host, or the emitting materials can be added by copolymerizing a minor constituent into a host polymer.

As described previously, an important relationship for choosing an emitting material is a comparison of the bandgap potential which is defined as the energy difference between the highest occupied molecular orbital and the lowest unoccupied molecular orbital of the molecule. For efficient energy transfer from the host to the emitting material, a necessary condition is that the band gap of the dopant is smaller than that of the host material. For phosphorescent emitters it is also important that the host triplet energy level of the host be high enough to enable energy transfer from host to emitting material.

Additional host and emitting materials known to be of use include, but are not limited to, those disclosed in U.S. Pat. No. 4,768,292, U.S. Pat. No. 5,141,671, U.S. Pat. No. 5,150,006, U.S. Pat. No. 5,151,629, U.S. Pat. No. 5,405,709, U.S. Pat. No. 5,484,922, U.S. Pat. No. 5,593,788, U.S. Pat. No. 5,645,948, U.S. Pat. No. 5,683,823, U.S. Pat. No. 5,755,999, U.S. Pat. No. 5,928,802, U.S. Pat. No. 5,935,720, U.S. Pat. No. 5,935,721, and U.S. Pat. No. 6,020,078.

Metal complexes of 8-hydroxyquinoline and similar derivatives (Formula E) constitute one class of useful additional host compounds capable of supporting electroluminescence, and are particularly suitable for light emission of wavelengths longer than 500 nm, e.g., green, yellow, orange, and red. 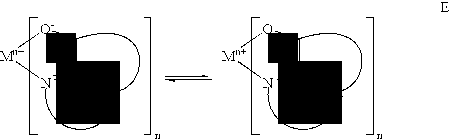
In Formula (E),

M represents a metal;

n is an integer of from 1 to 4; and

Z independently in each occurrence represents the atoms completing a nucleus having at least two fused aromatic rings.

From the foregoing it is apparent that the metal can be monovalent, divalent, trivalent, or tetravalent metal. The metal can, for example, be an alkali metal, such as lithium, sodium, or potassium; an alkaline earth metal, such as magnesium or calcium; an earth metal, such aluminum or gallium, or a transition metal such as zinc or zirconium. Generally any monovalent, divalent, trivalent, or tetravalent metal known to be a useful chelating metal can be employed.

Z completes a heterocyclic nucleus containing at least two fused aromatic rings, at least one of which is an azole or azine ring. Additional rings, including both aliphatic and aromatic rings, can be fused with the two required rings, if required. To avoid adding molecular bulk without improving on fimction the number of ring atoms is usually maintained at 18 or less.

Illustrative of useful chelated oxinoid compounds are the following:

CO-1: Aluminum trisoxine [alias, tris(8-quinolinolato)aluminum(III); Alq]

CO-2: Magnesium bisoxine [alias, bis(8-quinolinolato)magnesium(II)]

CO-3: Bis[benzo {f}-8-quinolinolato]zinc (II)

CO-4: Bis(2-methyl-8-quinolinolato)aluminum(III)-μ-oxo-bis(2-methyl-8-quinolinolato) aluminum(III)

CO-5: Indium trisoxine [alias, tris(8-quinolinolato)indium]

CO-6: Aluminum tris(5-methyloxine) [alias, tris(5-methyl-8-quinolinolato) aluminum(III)]

CO-7: Lithium oxine [alias, (8-quinolinolato)lithium(I)]

CO-8: Gallium oxine [alias, tris(8-quinolinolato)gallium(III)]

CO-9: Zirconium oxine [alias, tetra(8-quinolinolato)zirconium(IV)]

Certain derivatives of anthracene (Formula F) constitute one class of useful additional host materials capable of supporting electroluminescence, and are particularly suitable for light emission of wavelengths longer than 400 nm, e.g., blue, green, yellow, orange or red. Unsymmetric anthracene derivatives as disclosed in U.S. Pat. No. 6,465,115 and WO 2004/018587 are also useful hosts. 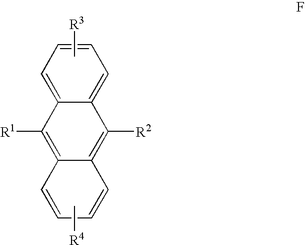
In Formula (F), R¹ and R² represent independently selected aryl groups, such as naphthyl, phenyl, biphenyl, triphenyl, anthracene.

In Formula (F), R³ and R⁴ represent one or more substituents on each ring where each substituent is individually selected from the following groups:

Group 1: hydrogen, or alkyl of from 1 to 24 carbon atoms;

Group 2: aryl or substituted aryl of from 5 to 20 carbon atoms;

Group 3: carbon atoms from 4 to 24 necessary to complete a fused aromatic ring of anthracenyl; pyrenyl, or perylenyl;

Group 4: heteroaryl or substituted heteroaryl of from 5 to 24 carbon atoms as necessary to complete a fused heteroaromatic ring of furyl, thienyl, pyridyl, quinolinyl or other heterocyclic systems;

Group 5: alkoxylamino, alkylamino, or arylamino of from 1 to 24 carbon atoms; and

Group 6: fluorine or cyano.

A useful class of anthracenes are derivatives of 9,10-di-(2-naphthyl)anthracene (Formula G). 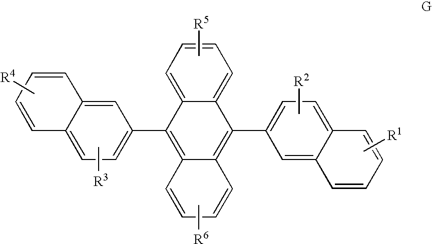
In Formula (G), R¹, R², R³, R⁴, R⁵, and R⁶ represent one or more substituents on each ring where each substituent is individually selected from the following groups:

Group 1: hydrogen, or alkyl of from 1 to 24 carbon atoms;

Group 2: aryl or substituted aryl of from 5 to 20 carbon atoms;

Group 3: carbon atoms from 4 to 24 necessary to complete a fused aromatic ring of anthracenyl; pyrenyl, or perylenyl;

Group 4: heteroaryl or substituted heteroaryl of from 5 to 24 carbon atoms as necessary to complete a fused heteroaromatic ring of furyl, thienyl, pyridyl, quinolinyl or other heterocyclic systems;

Group 5: alkoxylamino, alkylamino, or arylamino of from 1 to 24 carbon atoms; and

Group 6: fluorine or cyano.

Illustrative examples of additional anthracene materials for use in a light-emitting layer include: 2-(4-methylphenyl)-9,10-di-(2-naphthyl)-anthracene; 9-(2-naphthyl)- 10-(1,1′-biphenyl)-anthracene; 9,10-bis[4-(2,2-diphenylethenyl)phenyl]-anthracene, as well as the following listed compounds.

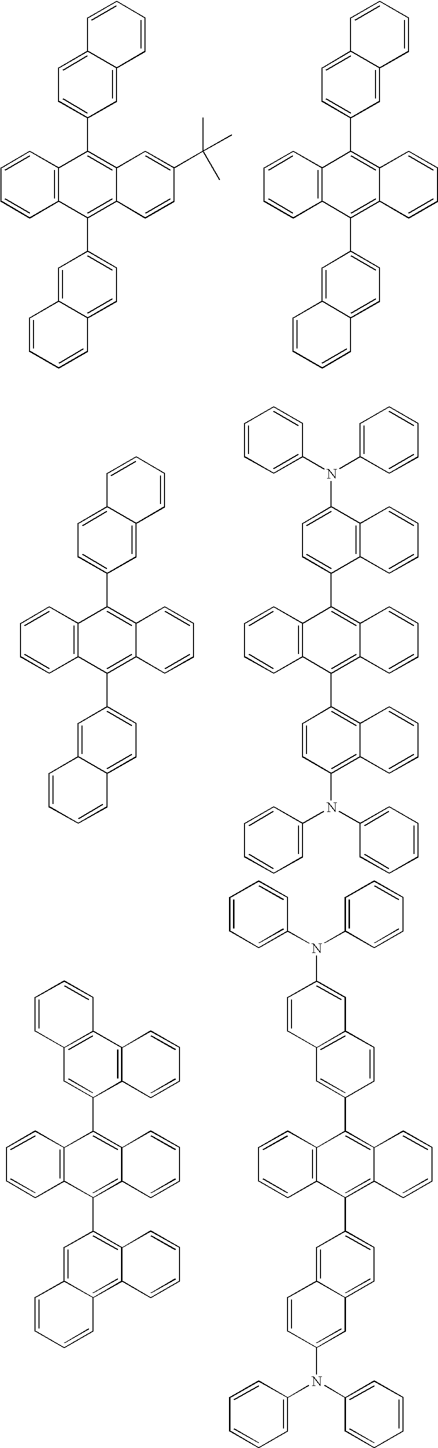

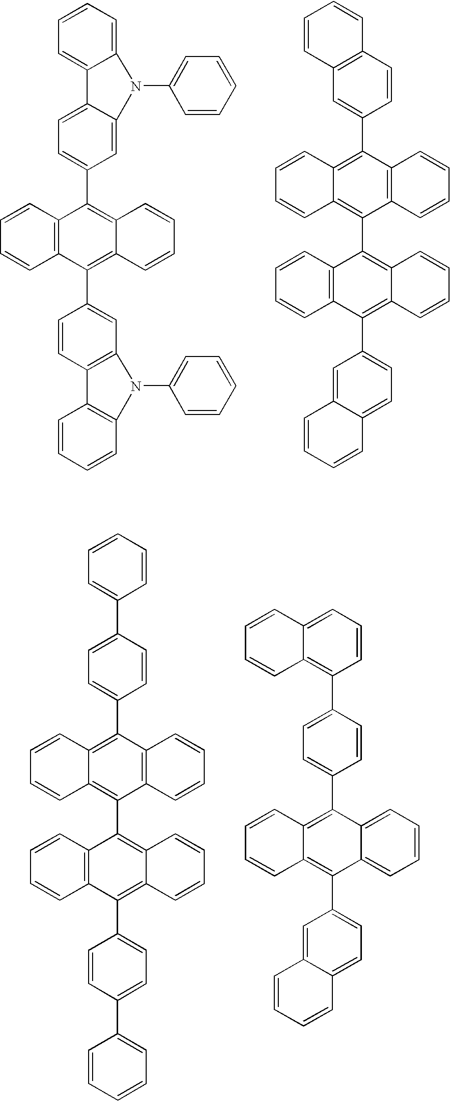

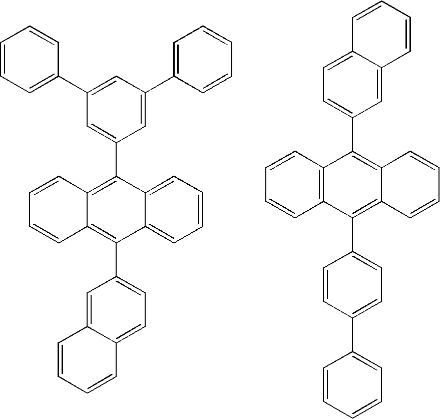

Benzazole derivatives (Formula H) constitute another class of useful additional host materials capable of supporting electroluminescence, and are particularly suitable for light emission of wavelengths longer than 400 nm, e.g., blue, green, yellow, orange or red. 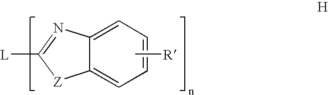
Where:

n is an integer of 3 to 8;

Z is O, NR or S; and

R and R+ are individually hydrogen; alkyl of from 1 to 24 carbon atoms, for example, propyl, t-butyl, heptyl, and the like; aryl or hetero-atom substituted aryl of from 5 to 20 carbon atoms for example phenyl and naphthyl, furyl, thienyl, pyridyl, quinolinyl and other heterocyclic systems; or halo such as chloro, fluoro; or atoms necessary to complete a fused aromatic ring;

L is a linkage unit consisting of alkyl, aryl, substituted alkyl, or substituted aryl, which conjugately or unconjugately connects the multiple benzazoles together. An example of a useful benzazole is 2,2′,2″-(1,3,5-phenylene)tris[1-phenyl-1H-benzimidazole].

Distyrylarylene derivatives are also useful additional hosts, as described in U.S. Pat. No. 5,121,029. Carbazole derivatives are particularly useful additional hosts for phosphorescent emitters.

Useful fluorescent emitting materials include, but are not limited to, derivatives of anthracene, tetracene, xanthene, perylene, rubrene, coumarin, rhodamine, and quinacridone, dicyanomethylenepyran compounds, thiopyran compounds, polymethine compounds, pyrilium and thiapyrilium compounds, fluorene derivatives, periflanthene derivatives, indenoperylene derivatives, bis(azinyl)amine boron compounds, bis(azinyl)methane compounds, and carbostyryl compounds.

Examples of useful phosphorescent materials are reported in WO 00/57676, WO 00/70655, WO 01/41512, WO 02/15645, US 2003/0017361, WO 01/93642, WO 01/39234, U.S. Pat. No. 6,458,475, WO 02/071813, U.S. Pat. No. 6,573,651, US 2002/0197511, WO 02/074015, U.S. Pat. No. 6,451,455, US 2003/0072964, US 2003/0068528, U.S. Pat. No. 6,413,656, U.S. Pat. No. 6,515,298, U.S. Pat. No. 6,451,415, U.S. Pat. No. 6,097,147, US 2003/0124381, US 2003/0059646, US 2003/0054198, EP 1 239 526, EP 1 238 981, EP 1 244 155, US 2002/0100906, US 2003/0068526, US 2003/0068535, JP 2003073387, JP 2003073388, US 2003/0141809, US 2003/0040627, JP 2003059667, JP 2003073665, and US 2002/0121638.

Illustrative examples of useful fluorescent and phosphorescent emitting materials include, but are not limited to, the following:

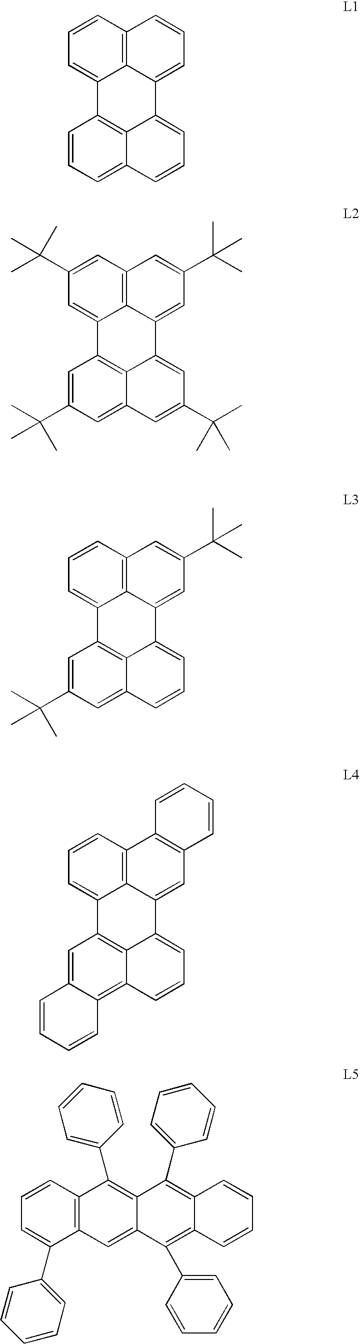

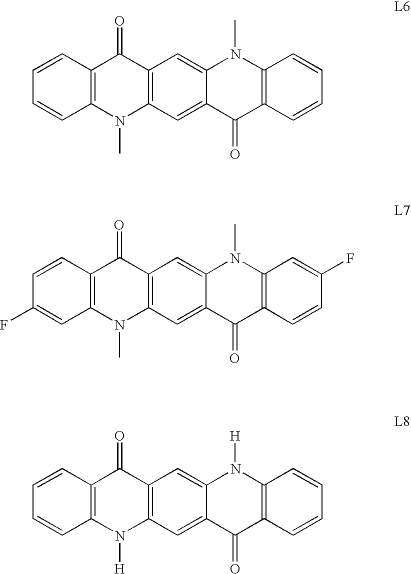

| | | |
|---|---|---|
| X | R1 | R2 |

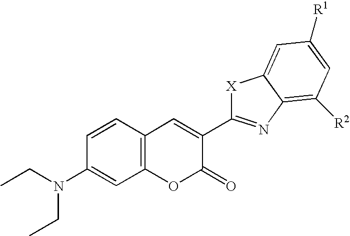

| | | | |
|---|---|---|---|
| L9 | O | H | H |
| L10 | O | H | Methyl |
| L11 | O | Methyl | H |
| L12 | O | Methyl | Methyl |
| L13 | O | H | t-butyl |
| L14 | O | t-butyl | H |
| L15 | O | t-butyl | t-butyl |
| L16 | S | H | H |
| L17 | S | H | Methyl |
| L18 | S | Methyl | H |
| L19 | S | Methyl | Methyl |
| L20 | S | H | t-butyl |
| L21 | S | t-butyl | H |
| L22 | S | t-butyl | t-butyl |

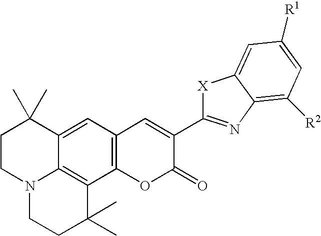

| | | | |
|---|---|---|---|
| L23 | O | H | H |
| L24 | O | H | Methyl |
| L25 | O | Methyl | H |
| L26 | O | Methyl | Methyl |
| L27 | O | H | t-butyl |
| L28 | O | t-butyl | H |
| L29 | O | tbutyl | t-butyl |
| L30 | S | H | H |
| L31 | S | H | Methyl |
| L32 | S | Methyl | H |
| L33 | S | Methyl | Methyl |
| L34 | S | H | tbutyl |
| L35 | S | t-butyl | H |
| L36 | S | t-butyl | t-butyl |

R

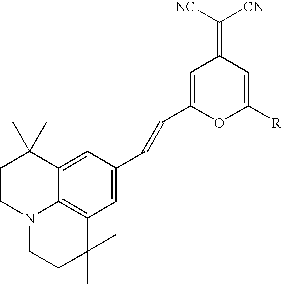

| | |
|---|---|
| L37 | phenyl |
| L38 | methyl |
| L39 | t-butyl |
| L40 | mesityl |

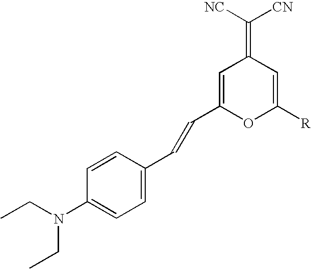

| | |
|---|---|
| L41 | phenyl |
| L42 | methyl |
| L43 | t-butyl |
| L44 | mesityl |

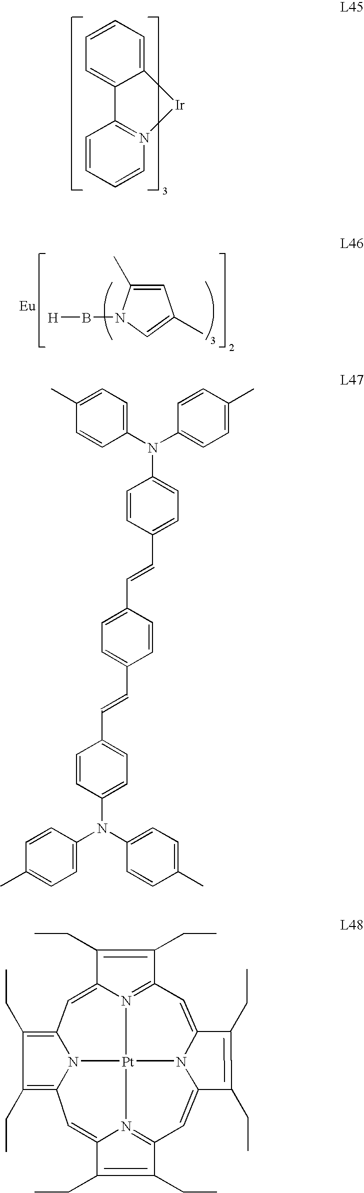 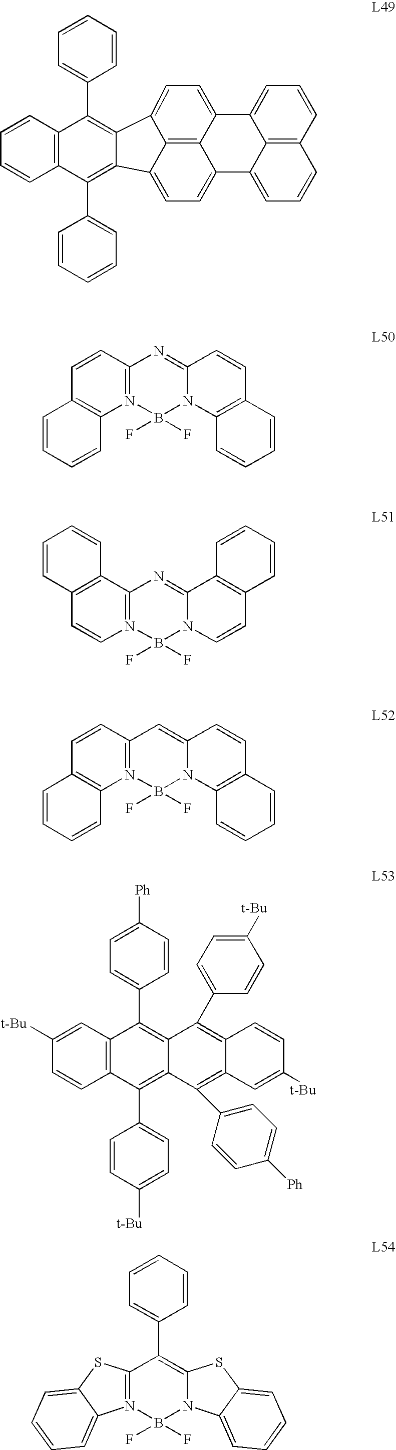 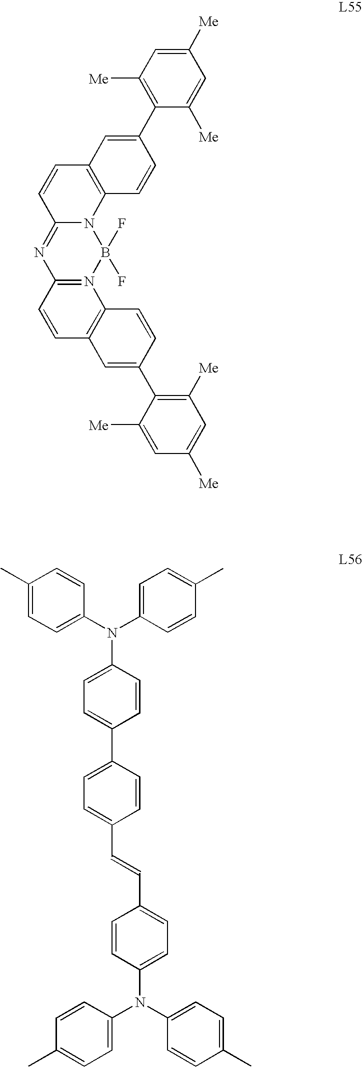 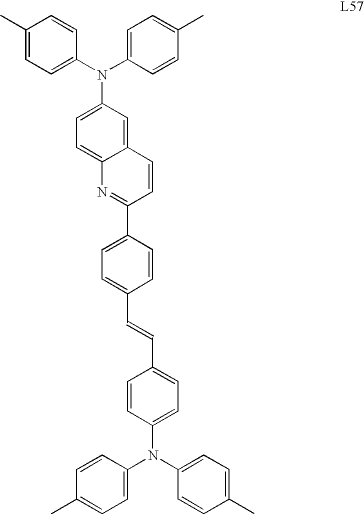 Electron-Transporting Layer (ETL)

In one embodiment, the anthracene compound of Formula (1) is included in an electron-transporting layer. Additional electron-transporting layers maybe present.

Preferred thin film-forming materials for use in forming the electron-transporting layer of the organic EL devices of this invention include metal chelated oxinoid compounds, including chelates of oxine itself (also commonly referred to as 8-quinolinol or 8-hydroxyquinoline). Such compounds help to inject and transport electrons and exhibit both high levels of performance and are readily fabricated in the form of thin films. Exemplary of contemplated oxinoid compounds are those satisfying structural Formula (E), previously described.

Other electron-transporting materials include various butadiene derivatives as disclosed in U.S. Pat. No. 4,356,429 and various heterocyclic optical brighteners as described in U.S. Pat. No. 4,539,507. Benzazoles satisfying structural Formula (H) are also useful electron transporting materials. Triazines are also known to be useful as electron transporting materials. Further useful materials are silacyclopentadiene derivatives described in EP 1,480,280; EP 1,478,032; and EP 1,469,533. Substituted 1,10-phenanthroline compounds such as are disclosed in JP2003-115387; JP2004-311184; JP2001-267080; and WO2002-043449. Pyridine derivatives are described in JP2004-200162 as useful electron transporting materials.

Electron-Injecting Layer (EIL)

Electron- injecting layers, when present, include those described in U.S. Pat. Nos. 5,608,287; 5,776,622; 5,776,623; 6,137,223; and 6,140,763, U.S. Pat. No. 6,914,269 the disclosures of which are incorporated herein by reference. An electron-injecting layer generally consists of a material having a work function less than 4.0 eV. A thin-film containing low work-function alkaline metals or alkaline earth metals, such as Li, Cs, Ca, Mg can be employed. In addition, an organic material doped with these low work-function metals can also be used effectively as the electron-injecting layer. Examples are Li- or Cs-doped Alq. In one suitable embodiment the electron-injecting layer includes LiF. In practice, the electron-injecting layer is often a thin layer deposited to a suitable thickness in a range of 0.1-3.0 nm.

Cathode

When light emission is viewed solely through the anode, the cathode used in this invention can be comprised of nearly any conductive material. Desirable materials have good film-forming properties to ensure good contact with the underlying organic layer, promote electron injection at low voltage, and have good stability. Useful cathode materials often contain a low work function metal (<4.0 eV) or metal alloy. One useful cathode material is comprised of a Mg:Ag alloy wherein the percentage of silver is in the range of 1 to 20%, as described in U.S. Pat. No. 4,885,221. Another suitable class of cathode materials includes bilayers comprising the cathode and a thin electron-injection layer (EIL) in contact with an organic layer (e.g., an electron transporting layer (ETL)) which is capped with a thicker layer of a conductive metal. Here, the EIL preferably includes a low work function metal or metal salt, and if so, the thicker capping layer does not need to have a low work function. One such cathode is comprised of a thin layer of LiF followed by a thicker layer of Al as described in U.S. Pat. No. 5,677,572. Other useful cathode material sets include, but are not limited to, those disclosed in U.S. Pat. Nos. 5,059,861; 5,059,862, and 6,140,763.

When light emission is viewed through the cathode, the cathode must be transparent or nearly transparent. For such applications, metals must be thin or one must use transparent conductive oxides, or a combination of these materials. Optically transparent cathodes have been described in more detail in U.S. Pat. No. 4,885,211, U.S. Pat. No. 5,247,190, JP 3,234,963, U.S. Pat. No. 5,703,436, U.S. Pat. No. 5,608,287, U.S. Pat. No. 5,837,391, U.S. Pat. No. 5,677,572, U.S. Pat. No. 5,776,622, U.S. Pat. No. 5,776,623, U.S. Pat. No. 5,714,838, U.S. Pat. No. 5,969,474, U.S. Pat. No. 5,739,545, U.S. Pat. No. 5,981,306, U.S. Pat. No. 6,137,223, U.S. Pat. No. 6,140,763, U.S. Pat. No. 6,172,459, EP 1 076 368, U.S. Pat. No. 6,278,236, and U.S. Pat. No. 6,284,3936. Cathode materials are typically deposited by any suitable method such as evaporation, sputtering, or chemical vapor deposition. When needed, patterning can be achieved through many well known methods including, but not limited to, through-mask deposition, integral shadow masking as described in U.S. Pat. No. 5,276,380 and EP 0 732 868, laser ablation, and selective chemical vapor deposition.

Other Useful Organic Layers and Device Architecture

In some instances, layers 109 and 111 can optionally be collapsed into a single layer that serves the function of supporting both light emission and electron transportation. It also known in the art that emitting materials may be included in the hole-transporting layer, which may serve as a host. Multiple materials may be added to one or more layers in order to create a white-emitting OLED, for example, by combining blue- and yellow-emitting materials, cyan- and red-emitting materials, or red-, green-, and blue-emitting materials. White-emitting devices are described, for example, in EP 1 187 235, US 20020025419, EP 1 182 244, U.S. Pat. No. 5,683,823, U.S. Pat. No. 5,503,910, U.S. Pat. No. 5,405,709, and U.S. Pat. No. 5,283,182 and may be equipped with a suitable filter arrangement to produce a color emission.

Additional layers such as electron or hole-blocking layers as taught in the art may be employed in devices of this invention. Hole-blocking layers may be used between the light emitting layer and the electron transporting layer. Electron-blocking layers may be used between the hole-transporting layer and the light emitting layer. These layers are commonly used to improve the efficiency of emission, for example, as in US 20020015859.

This invention may be used in so-called stacked device architecture, for example, as taught in U.S. Pat. No. 5,703,436 and U.S. Pat. No. 6,337,492.

Deposition of Organic Layers

The organic materials mentioned above are suitably deposited by any means suitable for the form of the organic materials. In the case of small molecules, they are conveniently deposited through sublimation, but can be deposited by other means such as from a solvent with an optional binder to improve film formation. If the material is a polymer, solvent deposition is usually preferred. The material to be deposited by sublimation can be vaporized from a sublimator “boat” often comprised of a tantalum material, e.g., as described in U.S. Pat. No. 6,237,529, or can be first coated onto a donor sheet and then sublimed in closer proximity to the substrate. Layers with a mixture of materials can utilize separate sublimator boats or the materials can be pre-mixed and coated from a single boat or donor sheet. Patterned deposition can be achieved using shadow masks, integral shadow masks (U.S. Pat. No. 5,294,870), spatially-defined thermal dye transfer from a donor sheet (U.S. Pat. No. 5,688,551, U.S. Pat. No. 5,851,709 and U.S. Pat. No. 6,066,357) and inkjet method (U.S. Pat. No. 6,066,357).

One preferred method for depositing the materials of the present invention is described in US 2004/0255857 and U.S. Ser. No. 10/945,941 where different source evaporators are used to evaporate each of the materials of the present invention. A second preferred method involves the use of flash evaporation where materials are metered along a material feed path in which the material feed path is temperature controlled. Such a preferred method is described in the following co-assigned patent applications: U.S. Ser. No. 10/784,585; U.S. Ser. No. 10/805,980; U.S. Ser. No. 10/945,940; U.S. Ser. No. 10/945,941; U.S. Ser. No. 11/050,924; and U.S. Ser. No. 11/050,934. Using this second method, each material may be evaporated using different source evaporators or the solid materials may be mixed prior to evaporation using the same source evaporator.

Encapsulation

Most OLED devices are sensitive to moisture or oxygen, or both, so they are commonly sealed in an inert atmosphere such as nitrogen or argon, along with a desiccant such as alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890. In addition, barrier layers such as SiOx, Teflon, and alternating inorganic/polymeric layers are known in the art for encapsulation.

Optical Optimization

OLED devices of this invention can employ various well-known optical effects in order to enhance its properties if desired. This includes optimizing layer thicknesses to yield maximum light transmission, providing dielectric mirror structures, replacing reflective electrodes with light-absorbing electrodes, providing anti glare or anti-reflection coatings over the display, providing a polarizing medium over the display, or providing colored, neutral density, or color conversion filters over the display. Filters, polarizers, and anti-glare or anti-reflection coatings may be specifically provided over the cover or as part of the cover.

Embodiments of the invention may provide advantageous features such as higher luminous yield, lower drive voltage, and higher power efficiency, longer operating lifetimes or ease of manufacture. Embodiments of devices useful in the invention can provide a wide range of hues including those useful in the emission of white light (directly or through filters to provide multicolor displays). Embodiments of the invention can also provide an area lighting device.

The invention and its advantages are further illustrated by the specific examples that follow. The term “percentage” or “percent” and the symbol “%” indicate the volume percent (or a thickness ratio as measured on a thin film thickness monitor) of a particular first or second compound of the total material in the layer of the invention and other components of the devices. If more than one second compound is present, the total volume of the second compounds can also be expressed as a percentage of the total material in the layer of the invention.

### EXAMPLE 1

### Preparation of Inv-12.

9,10-Dibromo-2-chloroanthracene was prepared by the following procedure. 2-Chloroanthracene (5g, 23.5 mmol, 1eq) was suspended in 100 mL of methylene chloride, followed by the addition of N-bromosuccinimide (8.36 g, 47 mmol, 2.0 eq). The slurry was stirred at room temperature, after 1 h only a trace of monobromo material was detected by thin layer chromatography analysis. The flask was heated in a warm water bath. Within a few minutes, the solution cleared and turned orange, followed by the precipitation of yellow solid. Stirring became difficult, therefore an additional portion of 50 mL of methylene chloride was added, and the mixture was stirred at room temperature for an additional hour, to completion. The yellow precipitate was isolated by filtration, and the solid cake washed with acetonitrile. During filtration, more solid had precipitated out in the filtering flask. A second crop of solid was isolated by filtration and combined with the first crop to yield a total of 8.1 g (93% yield) of 9,10-Dibromo-2-chloroanthracene as a bright yellow solid.

9,10-Dibromo-2-chloroanthracene (2.50 g, 6.74, 1 eq), 4-biphenylboronic acid (4.27 g, 21.5 mmol, 3.2 eq), palladium(II)acetate (31 mg, 2 eq %) and Sphos (2-(2′,6′-dimethoxybiphenyl)dicyclohexylphosphine, 75 mg, 2.7%) together with potassium phosphate monohydrate (13.9 g, 60.6 mmol, 9 eq) were combined as follows, in 100 mL toluene. In a vial, 50 mg of the bromide starting material, the palladium and Sphos were combined in 10 mL toluene (previously degassed). The solution was warmed up until all solids dissolved, then it was added to a degassed mixture of the rest of the bromide, the boronic acid, the base, and the rest of the toluene. The resulting mixture became darker. The mixture was left to stir at room temperature at first, during which time it became light yellow and thick. It was then stirred at 50-60° C. overnight. The mixture was then cooled to room temperature, diluted with more toluene (up to about 400 mL) and water. The toluene layer was washed with water (2×150 mL), dried over Na₂SO₄, and then concentrated to dryness. The solid residue was suspended in methylene chloride, and stirred over a warm water bath. The product was isolated by filtration (TLC indicated very clean material) as a light yellow solid (4.2 g, 98%). The solid was sublimed at 325° C. and afforded 3.59 g of Inv-12.

### EXAMPLE 2

### Fabrication of Device 1-1 through 1-6.

A series of EL devices (1-1 through 1-6) were constructed in the following manner.
1. A glass substrate coated with a 25 nm layer of indium-tin oxide (ITO), as the anode, was sequentially ultrasonicated in a commercial detergent, rinsed in deionized water, degreased in toluene vapor and exposed to oxygen plasma for about 1 min.
2. Over the ITO was deposited a 1 nm fluorocarbon (CFx) hole-injecting layer (HIL) by plasma-assisted deposition of CHF₃ as described in U.S. Pat. No. 6,208,075.
3. Next a layer of hole-transporting material 4,4′-Bis[N-(l -naphthyl)-N-phenylamino]biphenyl (NPB) was deposited to a thickness of 75 nm.
4. A light-emitting layer (LEL) at a thickness shown in Table 1a and corresponding to C-1 or Inv-1 (see Table 1a) and including light-emitting material, (D-1), at the level shown in Table 1a was then deposited.
5. An electron-transporting layer (ETL) of tris(8-quinolinolato)aluminum (III) (Alq), was vacuum-deposited over the LEL. The thickness of the ETL was adjusted (Table 1a) so that the each device fabricated had the same overall device thickness.
6. 0.5 nm layer of lithium fluoride was vacuum deposited onto the ETL, followed by a 150 nm layer of aluminum, to form a cathode layer.

The above sequence completed the deposition of the EL device. The device was then hermetically packaged in a dry glove box for protection against ambient environment.

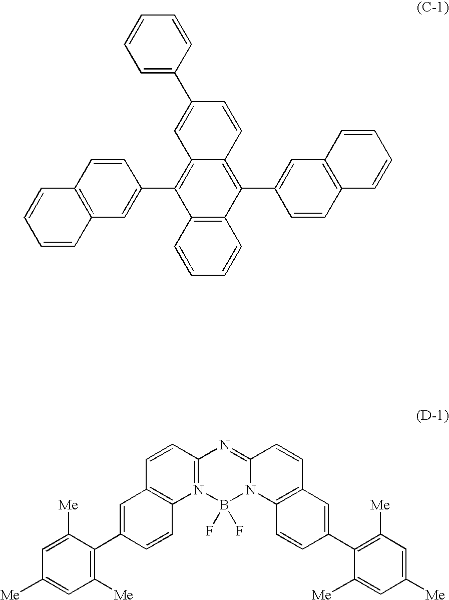

The devices were tested for luminous efficiency and color at an operating current of 20 mA/cm² and the results are reported in Table 1b in the form of luminous yield (cd/A) and efficiency (w/A), where device efficiency is the radiant flux (in watts) produced by the device per amp of input current, where radiant flux is the light energy produced by the device per unit time. Light intensity is measured perpendicular to the device surface, and it is assumed that the angular profile is Lambertian. The color of light produced by the devices is reported in 1931 CIE (Commission Internationale de L'Eclairage) coordinates. Drive voltage is reported in volts.

Device stability was determined by operating the device (40 mA/cm2) at ambient temperature (approximately 23° C.) for 500 hours. The percent luminance remaining after 500 hours relative to the initial luminance is listed in Table 1b.

TABLE 1a
LEL and ETL for Devices 1-1 through 1-6.

| | | | LEL | Emitter | ETL |
|---|---|---|---|---|---|
| | | LEL | Thick. | Level | Thick. |
| | Example | Host | (nm) | (%) | (nm) |
| 1-1 | Comparative | C-1 | 30 | 0.75 | 25 |
| 1-2 | Inventive | Inv-1 | 20 | 0.75 | 35 |
| 1-3 | Inventive | Inv-1 | 30 | 0.75 | 25 |
| 1-4 | Inventive | Inv-1 | 40 | 0.75 | 15 |
| 1-5 | Inventive | Inv-1 | 20 | 1.5 | 35 |
| 1-6 | Inventive | Inv-1 | 40 | 1.5 | 15 |

TABLE 1b
Evaluation results for Devices 1-1 through 1-6.

| | | | | Lum. | | | Stability |
|---|---|---|---|---|---|---|---|
| De- | | | | Yield | Eff. | Voltage | (500 h) |
| vice | Example | CIEx | CIEy | (cd/A) | (W/A) | (V) | % |
| 1-1 | Comparative | 0.151 | 0.147 | 2.60 | 0.055 | 7.07 | 80 |
| 1-2 | Inventive | 0.160 | 0.152 | 2.45 | 0.050 | 6.54 | 81 |
| 1-3 | Inventive | 0.149 | 0.128 | 2.47 | 0.058 | 6.71 | 82 |
| 1-4 | Inventive | 0.144 | 0.119 | 2.51 | 0.064 | 6.95 | 85 |
| 1-5 | Inventive | 0.155 | 0.147 | 2.50 | 0.053 | 6.43 | 84 |
| 1-6 | Inventive | 0.147 | 0.131 | 2.53 | 0.059 | 6.74 | 86 |

It can be seen from Table 1b that the devices that include Inv-1 have lower drive voltage relative to device 1-1 containing C-1. An improvement in device stability is also obtained.

### EXAMPLE 3

### Fabrication of Device 2-1 through 2-6.

A series of EL devices (2-1 through 2-6) were constructed in the same manner as devices 1-1 through 1-6 except the LEL host was C-1 or Inv-2 (see Table 2a). The LEL emitter (D-1) level, the thickness of the LEL, as well as the ETL thickness are also shown in Table 2a.

The devices were tested for luminous efficiency and color at an operating current of 20 mA/cm² and the results are reported in Table 2b in the 5 form of luminous yield (cd/A), efficiency (w/A) and 1931 CIE coordinates. Drive voltage is reported in volts.

Device stability was determined by operating the device (40 mA/cm²) at ambient temperature for 350 hours. The percent luminance remaining after 350 hours relative to the initial luminance is listed in Table 2b.

TABLE 2a
LEL and ETL for Devices 2-1 through 2-6.

| | | | LEL | Emitter | ETL |
|---|---|---|---|---|---|
| | | LEL | Thick. | Level | Thick. |
| | Example | Host | (nm) | (%) | (nm) |
| 2-1 | Comparative | C-1 | 30 | 0.75 | 25 |
| 2-2 | Inventive | Inv-2 | 20 | 0.75 | 35 |
| 2-3 | Inventive | Inv-2 | 30 | 0.75 | 25 |
| 2-4 | Inventive | Inv-2 | 40 | 0.75 | 15 |
| 2-5 | Inventive | Inv-2 | 20 | 1.5 | 35 |
| 2-6 | Inventive | Inv-2 | 40 | 1.5 | 15 |

TABLE 2b
Evaluation results for Devices 2-1 through 2-6.

| | | | | Lum. | | | Stability |
|---|---|---|---|---|---|---|---|
| De- | | | | Yield | Eff. | Voltage | (350 h) |
| vice | Example | CIEx | CIEy | (cd/A) | (W/A) | (V) | % |
| 2-1 | Comparative | 0.171 | 0.190 | 2.85 | 0.045 | 7.29 | 77 |
| 2-2 | Inventive | 0.153 | 0.142 | 2.62 | 0.056 | 6.59 | 83 |
| 2-3 | Inventive | 0.146 | 0.122 | 2.77 | 0.068 | 6.94 | 82 |
| 2-4 | Inventive | 0.143 | 0.113 | 2.72 | 0.072 | 7.09 | 85 |
| 2-5 | Inventive | 0.153 | 0.148 | 2.60 | 0.054 | 6.60 | 81 |
| 2-6 | Inventive | 0.143 | 0.121 | 2.63 | 0.065 | 7.25 | 83 |

As illustrated in Table 2b, devices using the host Inv-2 offer reduced voltage, higher luminance efficiency, and improved stability relative to device 2-1, which incorporates comparative host C-1.

### EXAMPLE 4

### Fabrication of Device 3-1 through 3-6.

A series of EL devices (3-1 through 3-6) were constructed in the manner as devices 1-1 through 1-6 except the LEL host was C-1 or Inv-3 (see Table 3a). The LEL emitter (D-1) level, the thickness of the LEL, as well as the ETL thickness are also shown in Table 3a.

The devices were tested for luminous efficiency and color at an operating current of 20 mA/cm² and the results are reported in Table 3b in the form of luminous yield (cd/A) and efficiency (w/A) and 1931 CIE coordinates. Drive voltage is reported in volts.

Device stability was determined by operating the device (40 mA/cm²) at ambient temperature for 350 hours. The percent luminance remaining after 350 hours relative to the initial luminance is listed in Table 3b.

TABLE 3a
LEL and ETL for Devices 3-1 through 3-6.

| | | | LEL | Emitter | ETL |
|---|---|---|---|---|---|
| | | LEL | Thick. | Level | Thick. |
| | Example | Host | (nm) | (%) | (nm) |
| 3-1 | Comparative | C-1 | 30 | 0.75 | 25 |
| 3-2 | Inventive | Inv-3 | 20 | 0.75 | 35 |
| 3-3 | Inventive | Inv-3 | 30 | 0.75 | 25 |
| 3-4 | Inventive | Inv-3 | 40 | 0.75 | 15 |
| 3-5 | Inventive | Inv-3 | 20 | 1.50 | 35 |
| 3-6 | Inventive | Inv-3 | 40 | 1.50 | 15 |

TABLE 3b
Evaluation results for Devices 3-1 through 3-6.

| | | | | Lum. | | | Stability |
|---|---|---|---|---|---|---|---|
| De- | | | | Yield | Eff. | Voltage | (350 h) |
| vice | Example | CIEx | CIEy | (cd/A) | (W/A) | (V) | % |
| 3-1 | Comparative | 0.157 | 0.157 | 2.43 | 0.048 | 6.29 | 76 |
| 3-2 | Inventive | 0.151 | 0.125 | 2.57 | 0.062 | 6.44 | 70 |
| 3-3 | Inventive | 0.144 | 0.110 | 2.64 | 0.071 | 7.56 | 70 |
| 3-4 | Inventive | 0.142 | 0.102 | 2.76 | 0.080 | 6.88 | 68 |
| 3-5 | Inventive | 0.150 | 0.127 | 2.64 | 0.062 | 6.44 | 76 |
| 3-6 | Inventive | 0.141 | 0.107 | 2.91 | 0.081 | 7.01 | 72 |

As can be seen from Table 3b, devices using the inventive host material, Inv-3, afford much higher luminance efficiency (up to 68% higher) relative to device 3-1, which has comparative C-1 as the host.

### EXAMPLE 5

### Fabrication of Device 4-1 through 4-8.

A series of EL devices (4-1 through 4-8) were constructed in the following manner.
1. A glass substrate coated with a 25 nm layer of indium-tin oxide (ITO), as the anode, was sequentially ultrasonicated in a commercial detergent, rinsed in deionized water, degreased in toluene vapor and exposed to oxygen plasma for about 1 min.
2. Over the ITO was deposited a 1 nm fluorocarbon (CFx) hole-injecting layer (HIL) by plasma-assisted deposition of CHF₃ as described in U.S. Pat. No. 6,208,075.
3. Next a layer of hole-transporting material 4,4′-Bis[N-(1-naphthyl)-N-phenylamino]biphenyl (NPB) was deposited to a thickness of 90 nm.
4. A light-emitting layer (LEL) at a thickness shown in Table 1a and corresponding to Inv-3, Inv-12, C-1, or C-2 (see Table 4a) and including light-emitting material, (D-1), at the level shown in Table 4a was then deposited.
5. An electron-transporting layer (ETL) of tris(8-quinolinolato)aluminum (III) (Alq), was vacuum-deposited over the LEL. The thickness of the ETL was adjusted (Table 4a) so that the each device fabricated had the same overall device thickness.
6. A 0.5 nm layer of lithium fluoride was vacuum deposited onto the ETL, followed by a 100 nm layer of aluminum, to form a cathode layer.

The above sequence completed the deposition of the EL device. The device was then hermetically packaged in a dry glove box for protection against ambient environment.

TABLE 4a
LEL and ETL for Devices 4-1 through 4-8.

C-2

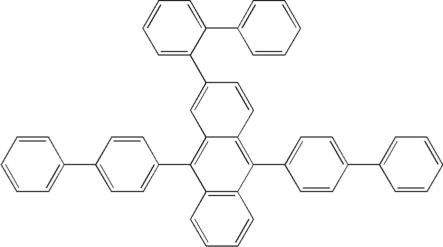

| | | | LEL | Emitter | ETL |
|---|---|---|---|---|---|
| | | LEL | Thick. | Level | Thick. |
| | Example | Host | (nm) | (%) | (nm) |
| 4-1 | Inventive | Inv-3 | 20 | 1.0 | 35 |
| 4-2 | Inventive | Inv-3 | 40 | 1.0 | 15 |
| 4-3 | Inventive | Inv-12 | 20 | 0.9 | 35 |
| 4-4 | Inventive | Inv-12 | 40 | 0.9 | 15 |
| 4-5 | Comparative | C-1 | 20 | 1.0 | 35 |
| 4-6 | Comparative | C-1 | 40 | 1.0 | 15 |
| 4-7 | Comparative | C-2 | 20 | 1.0 | 35 |
| 4-8 | Comparative | C-2 | 40 | 1.0 | 15 |

The devices were tested for luminous efficiency and color at an operating current of 20 mA/cm² and the results are reported in Table 4b in the form of luminous yield (cd/A) and efficiency (w/A) and 1931 CIE coordinates. Drive voltage is reported in volts.

Device stability was determined by operating the device (40 mA/cm²) at ambient temperature for 250 hours. The percent luminance remaining after 250 hours relative to the initial luminance is listed in Table 4b.

TABLE 4b
Evaluation results for Devices 4-1 through 4-8.

| | | | | Lum. | | | Stability |
|---|---|---|---|---|---|---|---|
| De- | | | | Yield | Eff. | Voltage | (250 h) |
| vice | Example | CIEx | CIEy | (cd/A) | (W/A) | (V) | % |
| 4-1 | Inventive | 0.155 | 0.147 | 2.90 | 0.061 | 7.26 | 76 |
| 4-2 | Inventive | 0.141 | 0.107 | 2.59 | 0.071 | 7.26 | 70 |
| 4-3 | Inventive | 0.161 | 0.179 | 2.52 | 0.045 | 6.59 | 76 |
| 4-4 | Inventive | 0.144 | 0.128 | 2.42 | 0.058 | 6.86 | 67 |
| 4-5 | Comparative | 0.157 | 0.173 | 3.11 | 0.058 | 7.26 | 76 |
| | (C-1) | | | | | | |
| 4-6 | Comparative | 0.141 | 0.133 | 3.13 | 0.073 | 7.53 | 72 |
| | (C-1) | | | | | | |
| 4-7 | Comparative | 0.158 | 0.161 | 2.92 | 0.057 | 6.97 | 58 |
| | (C-2) | | | | | | |
| 4-8 | Comparative | 0.145 | 0.122 | 2.78 | 0.068 | 7.29 | 47 |
| | (C-2) | | | | | | |

It can be seen from Table 4b that the inventive host materials afford, on average, devices with lower drive voltage relative to comparison material C-1 (device 4-5 and 4-6). The inventive host materials afford devices having much better stability relative to comparison material C-2 (device 4-7 and 4-8).

The entire contents of the patents and other publications referred to in this specification are incorporated herein by reference. The invention has been described in detail with particular reference to certain preferred embodiments thereof, but it will be understood that variations and modifications can be effected within the spirit and scope of the invention.

PARTS LIST

| | |
|---|---|
| 101 | Substrate |
| 103 | Anode |
| 105 | Hole-Injecting layer (HIL) |
| 107 | Hole-Transporting Layer (HTL) |
| 109 | Light-Emitting layer (LEL) |
| 111 | Electron-Transporting layer (ETL) |
| 112 | Electron-Injecting layer (EIL) |
| 113 | Cathode |
| 150 | Power Source |
| 160 | Conductor |

1. An OLED device comprising a cathode, an anode, and having therebetween a light emitting layer (LEL), at least one layer between the cathode and anode comprising a carbocyclic 2-aryl-9,10-biphenylanthracene compound containing a total of 8-12 aromatic rings, wherein the 6-substituent is hydrogen or an alkyl group and the 2-substituent is:
(A) an unsubstituted phenyl group;
(B) a phenyl group substituted with (a) a fluoro, a cyano, or an alkyl group or (b) a m- orp-phenyl group; or
(C) a substituted or unsubstituted fused ring aromatic group.

2. The device of claim 1 wherein the layer comprising a carbocyclic 2-aryl-9,10-biphenylanthracene compound is a light emitting layer.

3. The device of claim 2 wherein the layer emits blue or blue-green light.

4. The device of claim 1 wherein the 2-aryl-9,10-biphenylanthracene compound contains 8-10 rings.

5. The device of claim 1 wherein the 2-aryl-9,10-biphenylanthracene compound comprises a biphenyl group in the 9-position which is not the same as the biphenyl group in the 10-position.

6. The device of claim 1 wherein the 2-aryl-9,10-biphenylanthracene comprises a p-biphenyl substituent group in the 9- or 10-position.

7. The device of claim 1 wherein the 2-aryl-9,10-biphenylanthracene compound comprises a p-biphenyl substituent group in the 9-position and an independently selected p-biphenyl substituent group in the 10-position.

8. The device of claim 1 wherein the 2-aryl-9,10-biphenylanthracene compound comprises a p-biphenyl substituent group in the 9-or 10-position and an m-biphenyl substituent group in the 9- or 10-position.

9. The device of claim 1 wherein the 9,10-biphenyl groups of the 2-aryl-9,10-biphenylanthracene compound are not further substituted.

10. The device of claim 1 wherein the 2-substituent is an unsubstituted phenyl group.

11. The device of claim 1 wherein the 2-substituent is an aromatic group having fused rings.

12. The device of claim 1 wherein the 2-aryl-9,10-biphenylanthracene compound is represented by Formula (1): 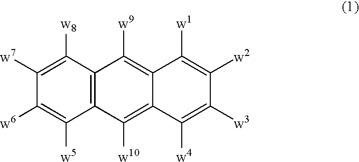
wherein:
w¹, w³, w⁴, w⁵, w⁷ and w⁸ represent hydrogen or an independently selected substituent group;
w² represents (A) an unsubstituted phenyl group; (B) a phenyl group substituted with (a) an alkyl, a fluoro, a cyano, or fused ring aryl group or (b) a m- or p-phenyl group; or (C) a substituted or unsubstituted fused ring aromatic group;
w⁶ represents hydrogen or an alkyl group; and
w⁹ and w¹⁰ represent independently selected biphenyl groups.

13. The device of claim 12 wherein w⁹ and w¹⁰ represent different biphenyl groups.

14. The device of claim 12 wherein w⁹ and w¹⁰ represent a p-biphenyl group and an m-biphenyl group.

15. The device of claim 1 wherein the layer comprising a carbocyclic 2-aryl-9,10-biphenylanthracene compound includes 0.5 to 8% by volume of a fluorescent light-emitting material.

16. The device of claim 1 wherein the layer comprising a carbocyclic 2-aryl-9,10-biphenylanthracene compound also includes a material that comprises a boron atom.

17. The device of claim 1 wherein the layer comprising a carbocyclic 2-aryl-9,10-biphenylanthracene compound also includes a material represented by Formula (2a) or Formula (2b): 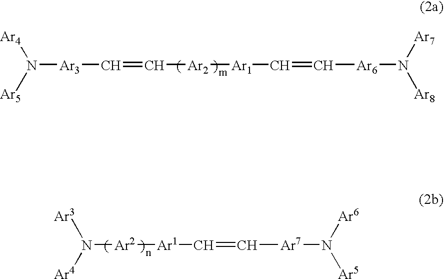
wherein:
Ar₁, each Ar₂, and Ar₃ through Ar₈ are independently selected aryl or heteroaryl groups, which may contain additional fused rings and provided that two aryl or heteroaryl rings may be joined;
m is 0 or 1;
Ar¹, each Ar², and Ar³ through Ar⁷ are independently selected aryl or heteroaryl groups, which may contain additional fused rings and provided that two aryl or heteroaryl rings may be joined, and;
n is 1,2or3.

18. The device of claim 1 wherein the layer comprising a carbocyclic 2-aryl-9,10-biphenylanthracene compound also includes a tertiary amine.

19. An OLED device comprising a cathode, an anode, and having therebetween a light emitting layer (LEL), at least one layer between the cathode and anode comprising a carbocyclic 2-aryl-9,10-biphenylanthracene compound containing a total of 8-12 aromatic rings, wherein the 9,10-substituents do not include fused rings and the 2-substituent is:
(A) an unsubstituted phenyl group;
(B) a phenyl group substituted with (a) a fluoro, a cyano, or an alkyl group or (b) a m- or p-phenyl group; or (C) a substituted or unsubstituted fused ring aromatic group.

20. The device of claim 19 wherein the 2-substituent is an unsubstituted phenyl group.
